(19) United States
(12) Patent Application Publication
(10) Pub. No.: US 2026/0262355 A1
(43) Pub. Date: Sep. 3, 2026

(54) PRODUCTION OF A LIGHTING DEVICE

(71) Applicant: ams-OSRAM International GmbH, Regensburg (DE)

(72) Inventors: Daniel Richter, Bad Abbach (DE); Gunnar Petersen, Regensburg (DE)

(21) Appl. No.: 18/996,577

(22) PCT Filed: Aug. 1, 2023
(86) PCT No.: PCT/EP2023/071256

§ 371 Date: Oct. 31, 2025

(30) Foreign Application Priority Data
Aug. 2, 2022 (DE) 10 2022 119 365.9

(51) Int. Cl. H10H 29/851; H10H 29/01

(52) U.S. Cl. CPC H10H 29/8514; H10H 29/012; H10H 29/0361

(57) ABSTRACT

In an embodiment a method includes providing a structured conversion element having separate conversion sections for radiation conversion arranged next to one another, wherein the conversion element comprises a carrier with recesses, which contain a conversion material, wherein the recesses of the carrier are through-recesses, and wherein a respective conversion section is formed by a recess of the carrier containing the conversion material, then forming an emitter group of radiation-emitting semiconductor chips arranged on the conversion element at one side of the conversion element, wherein a radiation-emitting semiconductor chip is present in a region of each of the conversion sections and then forming a stabilization layer at least laterally with respect to and between the radiation-emitting semiconductor chips.

### CROSS-REFERENCE TO RELATED APPLICATIONS

This patent application is a national phase filing under section 371 of PCT/EP2023/071256, filed Aug. 1, 2023, which claims the priority of German patent application no. 102022119365.9, filed Aug. 2, 2022, each of which is incorporated herein by reference in its entirety.

### TECHNICAL FIELD

The present invention relates to a method for producing a lighting device and to a lighting device.

### BACKGROUND

Pixelated lighting devices which may be used in the automobile sector in a headlamp of an adaptive front-lighting system (AFS) are known. Such lighting devices may comprise individually addressable light-emitting pixels, so that individual dynamic illumination scenarios can be implemented. In one possible configuration, an LED (light-emitting diode) arrangement is employed, which comprises emitters positioned next to one another in the form of LED chips with conversion elements for radiation conversion applied on the individual emitters. This approach is suitable for low-resolution FWL (forward lighting) concepts. The emitters may be laterally mirrored sapphire flip chips. The conversion elements may likewise be laterally mirrored and adhesively bonded onto the LED chips. In this configuration, radiation emerges laterally at the transition between the emitters and the connection elements. Furthermore, reflection takes place only on the perpendicularly running mirrored side walls of the emitters and conversion elements. This construction may therefore entail efficiency reductions.

### SUMMARY

According to one embodiment of the invention, a method for producing a lighting device is proposed. The method comprises providing a structured conversion element having separate conversion sections for radiation conversion arranged next to one another. The conversion element comprises a carrier with recesses which contain conversion material. The recesses of the carrier are in the form of through-recesses. The conversion sections are each formed by a recess of the carrier containing conversion material. The method furthermore comprises forming an emitter group of radiation-emitting semiconductor chips arranged on the conversion element at one side of the conversion element, a radiation-emitting semiconductor chip being present in the region of each of the conversion sections. Furthermore, a stabilization layer is formed at least laterally with respect to and between the radiation-emitting semiconductor chips.

The method offers the possibility of producing an efficient pixelated lighting device having radiation-emitting pixels arranged next to one another with high reliability. The pixels of the lighting device may respectively be formed by a conversion section of the conversion element and an associated radiation-emitting semiconductor chip, arranged in the region of the conversion section, of the emitter group. The emitter group is located at one side of the conversion element. Radiation emission during lighting operation of the lighting device may take place through a side of the conversion element opposite thereto. This side may form an emission side, or front side, of the lighting device. During lighting operation, the radiation-emitting semiconductor chips may generate a primary light radiation, which may be shone through the associated conversion sections of the conversion element and which the conversion sections can convert at least partially into a secondary light radiation. In this way, a corresponding light radiation may be output by the emission side of the lighting device. The lighting device may be produced in such a way that the radiation-emitting semiconductor chips can be driven separately from one another in order to generate radiation. In this respect, the lighting device may comprise individually drivable pixels so that individual dynamic illumination scenarios can be implemented.

The steps of the method may be carried out in the order mentioned above, i.e. the structured conversion element is provided, the emitter group is subsequently formed on the conversion element, and then the stabilization layer is formed. By providing the conversion element having the conversion sections and forming the emitter group with the radiation-emitting semiconductor chips present in the region of the conversion sections, it is possible to establish the respective position of the pixels and the distances between the pixels of the lighting device with high accuracy. Constant and also relatively small distances between the pixels may be implemented in this case, which makes seamless illumination possible. In the conversion element employed, the individual conversion sections are laterally surrounded by the carrier so that the carrier can form an optical barrier between the conversion sections and therefore pixels. In this way, optical crosstalk between the pixels may be suppressed and a high contrast may be achieved between the pixels. The conversion sections of the conversion element are connected to one another via the carrier. Thermal energy resulting from the radiation conversion may thereby be dissipated laterally from the conversion sections and distributed over the conversion element, which enables efficient cooling. Because of these properties, an efficient mode of operation of the lighting device is possible. With the aid of the stabilization layer which is formed at least laterally with respect to and between the radiation-emitting semiconductor chips, high mechanical stability may be imparted to the lighting device. The stabilization layer may also contribute to the optical partitioning and, depending on the configuration of the lighting device, may be used for radiation steering, which facilitates an efficient mode of operation.

Further possible details and embodiments, which may be envisioned for the method and for the lighting device producible according to the method, are described in more detail below.

The lighting device may be used in a headlamp of an adaptive front-lighting system of a vehicle.

During lighting operation of the lighting device, a mixed radiation comprising the primary and the secondary light radiation may be output by the emission side of the lighting device. The primary and the secondary light radiation may be a blue light radiation and a yellow light radiation, so that a white light radiation may be emitted overall.

The conversion sections of the conversion element may be arranged next to one another in a common plane, which may be the main extent plane of the conversion element. The conversion sections may also be arranged next to one another as a matrix in the form of rows and columns. The conversion element may comprise two opposite main sides, that is to say sides with the respectively largest lateral dimensions. The side of the conversion element on which the emitter is formed may be one of the main sides. The radiation emission may take place through the main side of the conversion element opposite thereto. This side may form the emission side, or front side, of the lighting device. The recesses of the carrier, which are in the form of through-recesses, or through-holes, may extend between the main sides of the conversion element.

The conversion material contained in the recesses of the carrier may comprise phosphor particles. The phosphor particles may be ceramic phosphor particles. The radiation conversion may be brought about with the aid of the phosphor particles. Furthermore, the conversion element may comprise a binder material by way of which the phosphor particles can be fixed inside the recesses of the carrier. The binder material may be a matrix material, or plastic material, in which the phosphor particles may be arranged, or embedded.

The carrier of the conversion element may be configured to be opaque for radiation, or light. The opacity may relate at least to a light radiation generated during operation by the lighting device. For this purpose, the carrier may be formed from a material that is opaque for radiation, or light. The opacity may also be implemented by a reflective configuration of the carrier. The carrier may for example be formed from silicon, ceramic, silicone filled with reflective particles or scattering particles (for example TiO2 particles), plastic, plastic with a reflective coating, or glass with a reflective coating. The reflective coating may be a metallic coating.

The carrier of the conversion element may, as indicated above, be formed from silicon. The providing of the conversion element may thereby take place in a reliable and accurate manner by employing production and structuring processes used in the semiconductor sector. Furthermore, efficient cooling is possible during operation of the lighting device. Besides silicon, the carrier may also comprise a further material, for example a metallic coating material.

In a further embodiment, the providing of the conversion element comprises the following. The carrier is provided having a configuration in which the carrier initially comprises cavities. Further steps are introducing conversion material into the cavities of the carrier and removing material at least of the carrier in such a way that the recesses of the carrier containing conversion material are formed from the cavities of the carrier. The geometrical structure of the conversion element having the conversion sections may thereby be established with high accuracy.

The conversion material employed may, as indicated above, be a binder material, or matrix material, containing phosphor particles. The conversion material may in this case be introduced into the cavities of the carrier for example by jetting, dosing, or dispensing, or by using a blade. It is also possible to introduce pure phosphor particles into the cavities of the carrier and subsequently to fix the phosphor particles in the cavities by depositing a binder material, for example aluminum oxide.

In order to form the recesses of the carrier from the cavities, material removal may be carried out over a wide area, for example by grinding. It is also possible to perform material removal selectively in the region of the cavities of the carrier, for example by etching. In this way, the conversion element may comprise indentations in the region of the conversion sections at the side intended for the emitter group, in the region of which the radiation-emitting semiconductor chips may be provided. The radiation-emitting semiconductor chips may in this case have smaller dimensions than the indentations of the conversion element. The indentations of the conversion element may be formed by the carrier protruding beyond the conversion material. In the region of the indentations of the conversion element, the carrier may furthermore have a shape that encloses the conversion material.

The providing of the conversion element may take place in a manner such that beam guiding, or beamforming, of the emitted light radiation is achieved by the recesses of the carrier. For this purpose, the following configurations may be envisioned.

In a further embodiment, the introducing of the conversion material into the cavities of the carrier takes place in such a way that the cavities are partially filled with the conversion material. The conversion material may in this case be located in a lower partial region, or bottom-side partial region, of the cavities and an upper partial region, or remaining partial region, of the cavities may be free from the conversion material. Correspondingly, the recesses of the carrier which result from the cavities may be filled with the conversion material in one partial region and be free from the conversion material in a further partial region, or emission-side partial region. Beam guiding may be achieved in the free partial region.

Beam guiding may furthermore be implemented, in addition or as an alternative to partial filling of the cavities, by sedimentation taking place after the introducing of the conversion material into the cavities of the carrier. With regard to this configuration, the conversion material may be introduced into the cavities of the carrier in the form of a binder material, or matrix material, containing phosphor particles, and the phosphor particles may settle in the direction of a bottom, or a bottom face, of the cavities. The sedimentation may be brought about by the influence of weight over time, or by centrifuging. In this way, the conversion material introduced into the cavities may have a density of phosphor particles, which increases in the direction of the bottom of the cavities. Correspondingly, the lighting device may be implemented in a manner such that there is a density of phosphor particles in the recesses of the carrier which result from the cavities, and therefore in the conversion sections of the conversion element, which increases in the direction of the radiation-emitting semiconductor chips. In an emission-side partial region, the recesses may comprise only the matrix material, or substantially only the matrix material, and no phosphor particles, or substantially no phosphor particles, so that beam guiding may be achieved in this partial region.

In a further embodiment, the cavities of the carrier comprise a bottom face and have a cross-sectional shape which broadens in a direction away from the bottom face. The conversion element may thereby be provided with recesses, which result from the cavities of the carrier and have a cross-sectional shape broadening at least partially in a direction away from the side intended for the emitter group. In this configuration, the recesses of the carrier may form reflector structures which bring about beamforming.

With regard to beam guiding, or beamforming, according to a further embodiment the providing of the conversion element comprises forming the carrier with a reflective coating which is present at least in the region of the recesses of the carrier. The reflective coating, on which radiation reflection may take place during operation of the lighting device, may be a metallic coating. For the forming of the reflective coating, a coating process may be carried out after the providing of the carrier having the cavities. Following this, the reflective coating may be removed outside the cavities of the carrier so that the emission side, or front side, of the lighting device may also be free from the reflective coating, or substantially free from the reflective coating. A high contrast may thereby be achieved between the pixels of the lighting device. Furthermore, a further coating process may be carried out after the forming of the recesses from the cavities of the carrier in order to provide the recesses fully with the reflective coating, and the reflective coating also generated in this case on the conversion material, or on the conversion sections, may subsequently be removed from the conversion material, or the conversion sections. This procedure may be envisioned when selective material removal is performed in the region of the cavities for the forming of the recesses from the cavities of the carrier.

The radiation-emitting semiconductor chips of the emitter group may comprise a front side, a back side opposite thereto, and lateral side walls extending between the front and back sides. The radiation-emitting semiconductor chips may furthermore comprise contacts, via which the semiconductor chips can be contacted and electrically supplied. The contacts may be present at the back side of the semiconductor chips.

The lighting device may be produced in such a way that the lighting device can be contacted and electrically supplied at a back side of the lighting device which is opposite to the emission side, or front side. Contacting may take place via backside contacts of the radiation-Docket emitting semiconductor chips of the emitter group or via a contact structure formed at the back side. In this context, the following configurations may be envisioned.

In a further embodiment, the radiation-emitting semiconductor chips comprise contacts at a back side, and the forming of the emitter group on the conversion element takes place in such a way that a front side of the radiation-emitting semiconductor chips faces toward the conversion element. In this configuration, the backside contacts of the semiconductor chips may themselves be employed as contacts of the lighting device. As an alternative, the following is also possible.

In a further embodiment, a contact structure connected to contacts of the radiation-emitting semiconductor chips is formed in the region of a side, or back side, of the radiation-emitting semiconductor chips facing away from the conversion element. In this configuration, the contact structure may be employed for contacting the lighting device. The contact structure may comprise conductor structures connected to contacts, or backside contacts, and contact elements, or contact pads, as well as optionally an insulating material, or at least one insulating layer. Furthermore, the contact structure may comprise at least one rewiring layer.

For the forming of the contact structure, a printed circuit board, or multilayer printed circuit board, may for example be provided and connected to the contacts of the radiation-emitting semiconductor chips and the stabilization layer. Forming of the contact structure may furthermore be carried out, for example, by alternating application of an insulating material and of a metallic material, together with corresponding structuring.

The forming of the stabilization layer takes place, as indicated above, at least laterally with respect to and between the radiation-emitting semiconductor chips. The stabilization layer may furthermore be generated in such a way that the stabilization layer is located at the back side of the semiconductor chips. The forming of the stabilization layer may be carried out with the aid of a molding process. It is also possible to cast material of the stabilization layer. If necessary, excess material of the stabilization layer may subsequently be removed. This may, for example, take place by grinding. In this way, backside faces of backside contacts of the radiation-emitting semiconductor chips may be exposed. It is also possible to form openings in the stabilization layer which reach as far as the contacts of the semiconductor chips. This may be used to subsequently form a contact structure connected to the contacts of the semiconductor chips.

The radiation-emitting semiconductor chips of the emitter group may be light-emitting diode or LED chips. In a further embodiment, the radiation-emitting semiconductor chips are volume emitters. In such volume-emitting semiconductor chips, radiation emission may take place through a front side and through lateral side walls. The lateral side walls may extend between the front side and an opposite back side. In this configuration, the semiconductor chips may be implemented in the form of flip chips and may comprise a frontside radiation-transmissive chip substrate, a backside semiconductor layer sequence arranged on the chip substrate and formed in order to generate radiation, and backside contacts. The chip substrate, which may be a sapphire substrate, may form the front side and a predominant part of the lateral side walls.

Volume emitters may involve a relatively simple chip technology. The use of volume emitters therefore enables simple and economical manufacture of the lighting device. Furthermore, the lighting device may be purposely produced in a form suitable for volume emitters, in order also to effectively use the light radiation output laterally through the lateral side walls of the volume-emitting semiconductor chips and to achieve efficient lighting operation of the lighting device. In this case, the following configurations may be envisioned.

In a further embodiment, the stabilization layer is a reflective layer. In this way, the stabilization layer may be used for radiation reflection during operation of the lighting device. For this purpose, the stabilization layer may be formed from a plastic material with reflective particles arranged, or embedded, therein. With regard to radiation reflection by the stabilization layer, the following may furthermore be envisioned.

In a further embodiment, at least in the region of lateral side walls of the radiation-emitting semiconductor chips, a transparent layer adjoining the radiation-emitting semiconductor chips is formed, which comprises in the region of the side walls a layer surface running curved and/or obliquely with respect to the side walls of the radiation-emitting semiconductor chips. The stabilization layer is formed adjoining the transparent layer present in the region of the semiconductor chips. The stabilization layer forms reflector structures surrounding the radiation-emitting semiconductor chips because of the layer surface of the transparent layer running curved and/or obliquely. During operation of the lighting device produced in this way, a radiation reflection and therefore radiation steering of a light radiation output through lateral side walls of the radiation-emitting semiconductor chips in the direction of the conversion element may be induced with the aid of the reflector structures formed by the stabilization layer, so that this radiation component can be supplied to the conversion material, or the conversion sections of the conversion element. This entails efficient utilization of the light radiation emitted through the lateral side walls of the semiconductor chips, and therefore a high photonic efficiency.

The transparent layer may be formed from a transparent plastic material, or adhesive material. It is possible to form its own transparent layer in the region of each of the radiation-emitting semiconductor chips, and therefore in total a plurality of separate transparent layers. Depending on the configuration, a single continuous transparent layer may also be formed.

In a further embodiment, the forming of the emitter group on the conversion element takes place in such a way that the radiation-emitting semiconductor chips are provided and are then arranged on the conversion element. This may take place by way of adhesive bonding. In this configuration of the method, the possibility of testing and/or presorting the radiation-emitting semiconductor chips is available before they are arranged on the conversion element. The lighting device may thereby be produced with high reliability according to established specifications with regard to the radiation emission, and productivity losses may be avoided.

If radiation-emitting semiconductor chips are provided and arranged on the conversion element, the arranging of the semiconductor chips and the forming of reflector structures may be carried out as follows.

According to a further embodiment, the conversion element provided comprises indentations in the region of the conversion sections at the side intended for the emitter group. The radiation-emitting semiconductor chips are arranged in the region of the indentations of the conversion element by using a transparent adhesive material. A transparent layer adjoining the radiation-emitting semiconductor chips in the region of a front side and of the side walls is respectively formed by the adhesive material, or by the adhesive material employed for arranging the semiconductor chips on the conversion element and additionally applying the adhesive material in the region of lateral side walls of the radiation-emitting semiconductor chips. During this process, the indentations of the conversion element act as a stop edge for the adhesive material, so that the transparent layer formed by the adhesive material comprises in the region of the side walls a layer surface running curved and/or obliquely with respect to the side walls of the radiation-emitting semiconductor chips. The stabilization layer is formed adjoining the transparent layer present in the region of the radiation-emitting semiconductor chips. In this case, the stabilization layer forms reflector structures surrounding the radiation-emitting semiconductor chips because of the layer surface of the transparent layer running curved and/or obliquely. As has been indicated above, a light radiation output through lateral side walls of the radiation-emitting semiconductor chips may in this way be deviated in the direction of the conversion element and used efficiently.

A configuration of the conversion element with indentations may, as described above, be implemented by selective material removal being carried out in the region of the cavities of the carrier which were previously provided with conversion material. Via the indentations, the conversion material may be exposed at the side of the conversion element which is intended for the emitter group. In order to arrange the radiation-emitting semiconductor chips in the region of the indentations of the conversion element, in which the semiconductor chips may be partially received in the indentations, the adhesive material employed may respectively be applied in the region of the indentations on the conversion element, or the conversion material present there, and the semiconductor chips may then be placed inside, or in the region of, the indentations and put on the adhesive material. They may be placed in an orientation of the semiconductor chips in which the front side, or a frontside radiation-transmissive chip substrate of the semiconductor chips, faces toward the conversion element. The adhesive material may in this case be displaced in such a way that wetting of the lateral side walls of the semiconductor chips with the adhesive material is induced. As an alternative, the adhesive material may be applied on the radiation-emitting semiconductor chips, or on their front side, and the semiconductor chips may then be placed inside, or in the region of, the indentations of the conversion material. Displacement of the adhesive material and wetting of the lateral side walls of the semiconductor chips with the adhesive material may also be brought about in this way. Depending on parameters such as the amount of adhesive material employed, additional application of the adhesive material in the region of the side walls of the semiconductor chips may take place after the placement of the radiation-emitting semiconductor chips in order to achieve sufficient wetting of the side walls with the adhesive material. During this procedure, the indications of the conversion element may act as a wetting stop edge for the adhesive material wetting the side walls of the semiconductor chips, so that the adhesive material does not emerge laterally beyond the indentations but remains in the region of the indentations and of the semiconductor chips placed there. For each of the radiation-emitting semiconductor chips, the adhesive material may thereby form in a self-aligned manner a transparent layer which adjoins a semiconductor chip in the region of the front side and the lateral side walls and comprises in the region of the side walls a layer surface running curved and/or obliquely with respect to the side walls. In this way, a plurality of separate transparent layers may be generated, that is to say its own transparent layer for each semiconductor chip. The stabilization layer, which is then formed adjoining the transparent layer respectively present in the region of the semiconductor chips, may thereby form reflector structures surrounding the radiation-emitting semiconductor chips.

The method may be carried out in such a way that a plurality of lighting devices are produced together. The structured conversion element may in this case be provided having lateral dimensions and a number of conversion sections for a plurality of lighting devices, or in the form of a conversion element panel, and a panel consisting of a plurality of contiguous lighting devices may be manufactured by forming the emitter group and forming the stabilization layer and optionally carrying out further steps, for example forming a contact structure connected to contacts of the radiation-emitting semiconductor chips. By carrying out singulation, the panel may then be divided into a plurality of separate lighting devices. The singulation may take place mechanically, for example by sawing.

Instead of mounting individual radiation-emitting semiconductor chips on the conversion element, the following procedure may furthermore be adopted.

In a further embodiment, the forming of the emitter group on the conversion element takes place in such a way that a wafer for the radiation-emitting semiconductor chips is provided, and the wafer is arranged on the conversion element and then singulated into the radiation-emitting semiconductor chips by cutting. By this procedure, production of the lighting device with constant distances between the pixels may be facilitated, or the effect may be achieved that a variation of distances between the pixels is relatively small, or minimal. Correspondingly, relatively small, or minimal, distances between the pixels may be implemented.

When the unsingulated wafer is being arranged on the conversion element, the wafer may be connected to the conversion element via a connecting material, or adhesive material. A wafer bonding method or adhesive bonding may in this case be carried out. The side of the conversion element on which the wafer is arranged may be planar. The cutting of the wafer in order to form singulated radiation-emitting semiconductor chips, and thereby the emitter group on the conversion element, may be carried out mechanically, for example by sawing. Partitioning trenches, which are located between the radiation-emitting semiconductor chips, may be formed by the cutting. At least material of the wafer, as well as of the conversion element, or of the carrier, may be removed during cutting. Furthermore, cutting may take place in multiple stages so that the partitioning trenches may have a stepped shape.

The wafer employed may comprise a frontside radiation-transmissive substrate and separate semiconductor layer sequences, which are arranged next to one at the back side of the radiation-transmissive substrate and are formed in order to generate radiation, as well as backside contacts. The radiation-transmissive substrate may be formed from sapphire. When the wafer is being cut, the radiation-transmissive substrate may be cut so that volume-emitting semiconductor chips with chip substrates resulting from the radiation-transmissive substrate may be formed.

The conversion element employed in the aforementioned configuration may, as described above, be provided with dimensions and conversion sections for a plurality of lighting devices, or in the form of a conversion element panel. By arranging the wafer on the conversion element, cutting it in order to provide the emitter group and forming the stabilization layer, and optionally further steps, for example forming a contact structure, a panel consisting of a plurality of contiguous lighting devices may be manufactured. The panel may then be singulated into a plurality of lighting devices.

With regard to the aforementioned configuration, a reflective coating may be formed on the radiation-emitting semiconductor chips and on the conversion element between the semiconductor chips before the stabilization layer is formed. The reflective coating may be a metallic coating. In order to avoid a possible occurrence of a short circuit because of the reflective coating, an insulation layer may be formed before the reflective coating is formed.

If a wafer is arranged on the conversion element and the wafer is cut into the radiation-emitting semiconductor chips, the forming of reflector structures may be carried out as follows.

According to a further embodiment, a transparent material is applied in the region of lateral side walls of the radiation-emitting semiconductor chips in order to form a transparent layer adjoining the radiation-emitting semiconductor chips, which comprises in the region of the side walls a layer surface running curved and/or obliquely with respect to the side walls of the radiation-emitting semiconductor chips. The stabilization layer is formed adjoining the transparent layer. The stabilization layer in this case forms reflector structures surrounding the radiation-emitting semiconductor chips because of the layer surface of the transparent layer running curved and/or obliquely. In this configuration, as indicated above, a light radiation output through lateral side walls of the radiation-emitting semiconductor chips may be deviated in the direction of the conversion element and thereby used efficiently.

The transparent material employed in the aforementioned embodiment may be a transparent plastic material, or adhesive material. The transparent material may be introduced into the partitioning trenches formed as a result of the cutting of the wafer between the radiation-emitting semiconductor chips. The lateral side walls of the semiconductor chips may in this case be wetted with the transparent material so that the transparent material forms a transparent layer, which adjoins the radiation-emitting semiconductor chips in the region of the side walls and has a layer surface running curved and/or obliquely with respect to the side walls. The stabilization layer then formed may in this way form reflector structures surrounding the semiconductor chips. The application, or introducing, of the transparent material may take place in such a way that a single continuous transparent layer is generated.

According to a further embodiment of the invention, a lighting device is proposed. The lighting device comprises a structured conversion element having separate conversion sections for radiation conversion arranged next to one another. The conversion element comprises a carrier with recesses which contain conversion material. The recesses of the carrier are in the form of through-recesses. The conversion sections are each formed by a recess of the carrier containing conversion material. The lighting device furthermore comprises an emitter of radiation-emitting semiconductor chips arranged on the conversion element at one side of the conversion element. A radiation-emitting semiconductor chip is present in the region of each of the conversion sections. A further component of the lighting device is a stabilization layer formed at least laterally with respect to and between the radiation-emitting semiconductor chips.

In the lighting device, the conversion sections of the conversion element together with the associated radiation-emitting semiconductor chips present in the region of the conversion sections may form radiation-emitting pixels of the lighting device. During lighting operation, a primary light radiation generated by the semiconductor chips may shine through the conversion sections and the conversion sections may at least partially convert the primary light radiation into a secondary light radiation. A corresponding light radiation may thereby be output by an emission side, or front side, of the lighting device. The emission side is formed by a side of the conversion element which is opposite to the side on which the emitter group is located. The lighting device may be distinguished by constant and small distances between the pixels. Because of the carrier which laterally surrounds the individual conversion sections, optical crosstalk between the pixels may be suppressed and a high contrast may be achieved between the pixels. The carrier also enables efficient cooling. Efficient lighting operation of the lighting device is thereby possible. The stabilization layer may impart high mechanical stability to the lighting device. Furthermore, the stabilization layer may contribute to the optical partitioning of the pixels and, depending on the configuration of the lighting device, may be used for radiation steering.

The lighting device may be produced according to the method described above or according to one or more of the embodiments of the method which are described above. Features and details as described above may therefore be employed correspondingly. For example, the following configurations are possible.

The conversion material may comprise phosphor particles, or ceramic phosphor particles. Furthermore, the conversion element may comprise a binder material by way of which the phosphor particles can be fixed inside the recesses of the carrier.

The lighting device may be implemented in such a way that beam guiding, or beamforming, can be brought about by the recesses of the carrier. For this purpose, the recesses of the carrier may be partially filled with conversion material. The recesses may in this case be free from the conversion material in an emission-side partial region.

In addition or as an alternative, the conversion material may be formed in the recesses of the carrier in a segmented form. The conversion material may in this case have a density of phosphor particles which increases in the direction of the side of the conversion element intended for the emitter group. In an emission-side partial region, the recesses may comprise only the matrix material, or substantially only the matrix material, and no phosphor particles, or substantially no phosphor particles.

In addition or as an alternative, the recesses of the carrier may have a cross-sectional shape which broadens at least partially in a direction away from the side of the conversion element intended for the emitter group. The recesses may thereby form reflector structures.

In a further embodiment, the carrier comprises a reflective coating at least in the region of the recesses. A radiation reflection may take place on the reflective coating during operation of the lighting device. The emission side of the lighting device may be free, or substantially free, from the reflective coating, so that a high contrast may be achieved between the pixels of the lighting device.

The radiation-emitting semiconductor chips of the emitter group may be connected to the conversion element via a transparent connecting material, or adhesive material.

In a further embodiment, the radiation-emitting semiconductor chips comprise contacts at a back side, and a front side of the radiation-emitting semiconductor chips faces toward the conversion element. In this configuration, the backside contacts of the semiconductor chips may be used as contacts of the lighting device in order to contact and electrically supply the lighting device.

In a further embodiment, the lighting device comprises a contact structure connected to contacts of the radiation-emitting semiconductor chips in the region of a side of the radiation-emitting semiconductor chips facing away from the conversion element. Contacting and electrical supply of the lighting device may take place via the contact structure. The contact structure may comprise conductor structures connected to contacts of the semiconductor chips, and contact elements, as well as optionally an insulating material, or at least one insulating layer.

In a further embodiment, the radiation-emitting semiconductor chips of the emitter group are volume emitters. In this way, the lighting device may be produced economically. The lighting device may also be implemented in such a way that a light radiation output through lateral side walls of the volume-emitting semiconductor chips is used efficiently. This may be achieved as follows.

In a further embodiment, the stabilization layer is a reflective layer. The stabilization layer is thereby suitable for radiation reflection.

In a further embodiment, at least in the region of lateral side walls of the radiation-emitting semiconductor chips, a transparent layer adjoining the radiation-emitting semiconductor chips is formed, which comprises in the region of the side walls a layer surface running curved and/or obliquely with respect to the side walls of the radiation-emitting semiconductor chips. The stabilization layer adjoins the transparent layer and forms reflector structures surrounding the radiation-emitting semiconductor chips because of the layer surface of the transparent layer running curved and/or obliquely. In this way, radiation reflection, or radiation steering, of a light radiation output through lateral side walls of the radiation-emitting semiconductor chips in the direction of the conversion element may be induced, which enables efficient use of this radiation component. The transparent layer may also be located in the region of a front side, or between the front side of the radiation-emitting semiconductor chips and the conversion element.

The conversion element may comprise indentations at the side intended for the emitter group in the region of the conversion sections. The radiation-emitting semiconductor chips may be arranged in the region of the indentations of the conversion element. The semiconductor chips may in this case be partially received in the indentations. This configuration may be employed in order to enable production of the transparent layer with a layer surface running curved and/or obliquely with respect to the side walls of the radiation-emitting semiconductor chips in a self-aligned manner.

### BRIEF DESCRIPTION OF THE DRAWINGS

The above-described properties, features and advantages of the invention, as well as the way in which they are achieved, become clearer and more easily understandable in conjunction with the following description of the exemplary embodiments, which are explained in more detail in connection with the schematic drawings, in which:

FIGS. 1 and 2 show a plan representation and a side representation of a lighting device comprising a conversion element having a plurality of conversion sections, an emitter group of radiation-emitting semiconductor chips arranged at one side on the conversion element, a stabilization layer which is formed laterally with respect to and between the semiconductor chips, and a backside contact structure;

FIG. 3 shows a configuration of a conversion material having a binder material and phosphor particles;

FIG. 4 shows a configuration of the stabilization layer having a plastic material and reflective particles;

FIG. 5 shows a side representation of a radiation-emitting semiconductor chip, radiation emission from a front side and lateral side walls being indicated;

FIG. 6 shows a further side representation of the lighting device; radiation emission being indicated;

FIGS. 7 to 13 show production of the lighting device with the aid of side representations, the conversion element being generated with a carrier having a shape that encloses a conversion material at the back side;

FIGS. 14 to 19 show production of the lighting device with the aid of side representations, the forming of the emitter group taking place by arranging separate radiation-emitting semiconductor chips on the conversion element;

FIGS. 20 to 22 show production of the lighting device with the aid of side representations according to a further configuration, the carrier of the conversion element being generated with a shape that does not enclose the conversion material at the back side;

FIGS. 23 to 26 show production of the lighting device with the aid of side representations according to a further configuration, the conversion element being generated in such a way that recesses of the carrier are partially filled with the conversion material;

FIGS. 27 to 29 show production of the lighting device with the aid of side representations according to a further configuration, the conversion element being generated in such a way that the conversion material is present in a sedimented form in recesses of the carrier;

FIGS. 30 to 33 show production of the lighting device with the aid of side representations according to a further configuration, the conversion element being generated in such a way that the carrier comprises recesses which widen in a direction away from the emitter group;

FIGS. 34 to 35 show production of the lighting device with the aid of side representations according to a further configuration, the contact structure being generated by using openings in the stabilization layer;

FIGS. 36 to 42 show production of the lighting device with the aid of side representations according to a further configuration, the forming of the emitter group taking place by arranging a wafer on the conversion element and subsequently cutting the wafer into radiation-emitting semiconductor chips; and

FIGS. 43 and 44 show production of the lighting device with the aid of side representations according to a further configuration, transparent material being introduced into partitioning trenches between the radiation-emitting semiconductor chips after the wafer has been cut.

### DETAILED DESCRIPTION OF ILLUSTRATIVE EMBODIMENTS

Possible configurations of a lighting device 100 implemented as a pixelated light source, and of an associated method for its production, are described with the aid of the following schematic figures. The lighting device 100, which comprises a plurality of radiation-Docket emitting pixels 105 arranged next to one another, may be used in a headlamp of an adaptive front-lighting system of a vehicle. The lighting device 100 may be distinguished by an efficient mode of operation.

It is to be pointed out that the schematic figures may not be to scale. Components and structures shown in the figures may therefore be represented exaggeratedly large or small for better understanding. In addition, it is to be pointed out that features and details which are mentioned in relation to one configuration may also be employed in relation to other configurations, and a plurality of configurations and their features may be combined with one another. Features corresponding to one another may be described in detail merely with reference to one configuration.

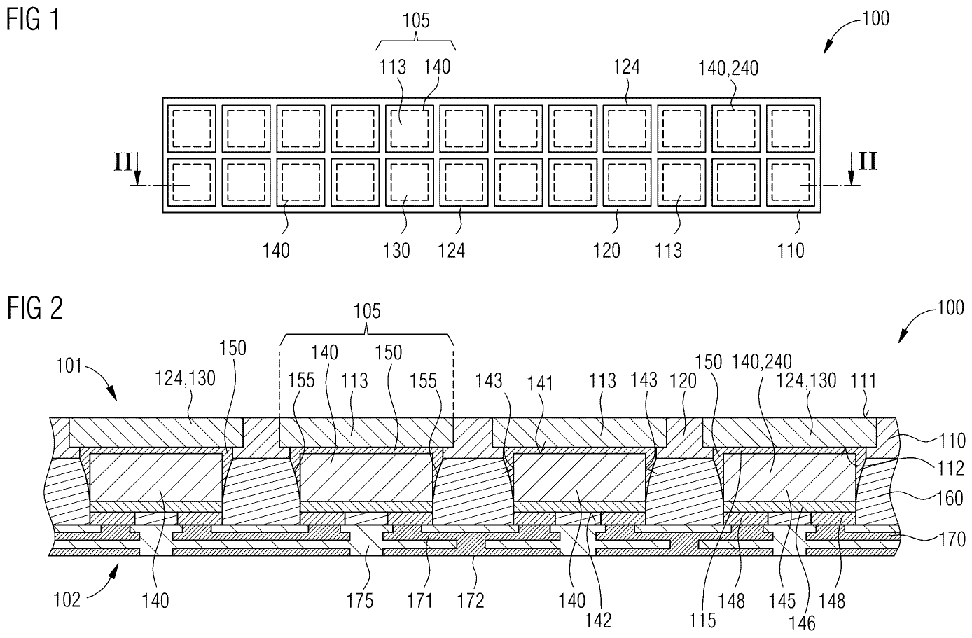

FIGS. 1 and 2 show a plan representation and a side sectional representation of a pixelated lighting device 100 according to one possible configuration. The plan representation of FIG. 1 indicates a section line which relates to the section plane of FIG. 2. FIG. 2 shows a detail of the lighting device 100. The lighting device 100 comprises a structured conversion element 110 having separate conversion sections 113 for radiation conversion arranged next to one another and an emitter group 240 of radiation-emitting semiconductor chips 140, which is arranged on the conversion element 110. The conversion sections 113 of the multipixel conversion element 110 are arranged next to one another in a main extent plane of the conversion element 110. Correspondingly, the radiation-emitting semiconductor chips 140 are arranged next to one another in a common plane. The semiconductor chips 140 may be LED (light-emitting diode) chips, which are implemented as described below in the form of volume emitters. The emitter group 240 may therefore also be referred to as an LED arrangement. The conversion element 110 comprises two opposite main sides 111, 112, which are also referred to below as the front side 111 and back side 112. The emitter group 240 is located at the back side 112 of the conversion element 110. There is a semiconductor chip 140 in the region of each conversion section 113 of the conversion element 110. A conversion section 113 and an associated semiconductor chip 140 in this case respectively form a light-emitting pixel 105 of the lighting device 100. The lighting device 100 is formed in such a way that the semiconductor chips 140 can be electrically driven separately in order to emit radiation. In this respect, the lighting device 100 comprises individually drivable pixels 105. Individual dynamic illumination scenarios may thereby be implemented.

The front side 111 of the pixelated conversion element 110 at the same time forms a front side 101 of the lighting device 100, through which an emission of light radiation 202 may take place during operation (cf. FIG. 6). The front side 101 of the lighting device 100 may therefore also be referred to as the emission side. FIG. 1 shows a plan view of the front side 101 of the lighting device 100, and therefore the front side 111 of the conversion element 110.

The conversion element 110 comprises a carrier 120 with recesses 124, which pass fully through the carrier 120 between the main sides 111, 112. In each recess 124, there is a conversion material 130 by which a radiation conversion may be brought about. The conversion sections 113 of the conversion element 110 are each formed by a recess 124 of the carrier 120, which contains a conversion material 130. With the aid of FIG. 1, it is clear that the recesses 124 of the carrier 120, and therefore the conversion sections 113 of the conversion element 110, are arranged next to one another as a matrix in the form of rows and columns. This applies similarly to the radiation-emitting semiconductor chips 140 respectively arranged centrally in the region of conversion sections 113. The recesses 124 of the carrier 120 and conversion sections 113 of the conversion element 110 also have a rectangular, or square, shape in plan view corresponding to the semiconductor chips 140. In the configuration shown in FIGS. 1 and 2, the semiconductor chips 140 furthermore have smaller lateral dimensions than the recesses 124 and conversion sections 113. The recesses 124 and conversion sections 113 may have lateral dimensions in the micrometer to millimeter range. The same applies to the semiconductor chips 140. The conversion sections 113 may, for example, have lateral dimensions in a range of from 2 mm×2 mm to 25 μm×25 μm.

According to the exemplary configuration depicted in FIG. 1, the lighting device 100 comprises twenty-four conversion sections 113 and therefore pixels 105, which are arranged in the form of two rows and twelve columns. In contrast thereto, the lighting device 100 may also be implemented with a different number and arrangement of conversion sections 113 and pixels 105.

The carrier 120 of the conversion element 110 may be formed from silicon. Furthermore, the carrier 120 may be provided with a reflective coating 128 (cf. FIG. 6), as is explained in more detail below.

As is represented in FIG. 2, the conversion element 110 comprises indentations 115 at the back side, and therefore a structured back side 112. The light-emitting semiconductor chips 140 are arranged in the region of the indentations 115 of the conversion element 110 and are partially, or to a small extent, received in the indentations 115 (cf. also FIG. 6). The indentations 115 of the conversion element 110 are implemented by the carrier 120 respectively protruding beyond the conversion material 130 at the back side 112. The indentations 115 form a part of the recesses 124 of the carrier 120. According to the configuration shown in FIG. 2, the carrier 120 furthermore has a shape that encloses the conversion material 130 in the region of the indentations 115, so that the recesses 124 have a stepped shape and stepped inner sides in cross section.

The radiation-emitting semiconductor chips 140 of the emitter group 240 comprise a front side 141, a back side 142 opposite to the front side 141, and lateral side walls 143 extending between the front and back sides 141, 142. In the lighting device 100, as shown in FIG. 2, the semiconductor chips 140 are positioned in such a way that the front side 141 of the semiconductor chips 140 faces toward the conversion element 110 and the back side 142 of the semiconductor chips 140 faces away from the conversion element 110. The radiation-emitting semiconductor chips 140 furthermore comprise two contacts 148 at the back side 142, via which the semiconductor chips 140 can be contacted and electrically supplied (cf. also FIG. 5).

As is furthermore represented in FIG. 2, the radiation-emitting semiconductor chips 140 are connected to the conversion element 110 via a transparent layer 150. There is a transparent layer 150 in the region of each semiconductor chip 140. The transparent layer 150 adjoins both the front side 141 and the lateral side walls 143 of a corresponding semiconductor chip 140, so that the semiconductor chip 140 is surrounded by the transparent layer 150 both on the front side and circumferentially. In the region of the lateral side walls 143, the transparent layer 150 has a layer surface 155 running curved and/or obliquely with respect to the side walls 143. The transparent layer 150 furthermore adjoins the back side of the conversion element 110 in the region of a corresponding indentation 115. As is described below, the transparent layer 151 serves for each of the semiconductor chips 140 as an optical transition element for efficient utilization of a light radiation 201 generated by the semiconductor chips 140.

A further constituent part of the lighting device 100 is a reflective stabilization layer 160, which is formed at the back side of the conversion element 110 and is located laterally with respect to and between the radiation-emitting semiconductor chips 140 of the emitter group 240. The stabilization layer 160 is located at the back side 142 of the semiconductor chips 140. Backside faces of the contacts 148 of the semiconductor chips 140 are in this case free from the stabilization layer 160, or the stabilization layer 160 ends flush with the backside faces of the contacts 148. The stabilization layer 160 adjoins the carrier 120 of the conversion element 110 and to the transparent layers 150 surrounding the semiconductor chips 140, and likewise comprises a layer surface running curved and/or obliquely with respect to the lateral side walls 143 of the semiconductor chips 140 in the region of the semiconductor chips 140, in a manner corresponding to the layer surface 155 of the transparent layers 150. The stabilization layer 160 may thereby form reflector structures for radiation steering, which surround the semiconductor chips 140.

The lighting device 100 furthermore comprises a backside contact structure 170, which is formed on the stabilization layer 160 and on the radiation-emitting semiconductor chips 140, or their contacts 148. Via the contact structure 170, the lighting device 100 can be contacted and the lighting device 100 and its semiconductor chips 140 can be electrically supplied. The contact structure 170 comprises metallic conductor structures 171, which are electrically connected to the contacts 148 of the semiconductor chips 140, and an insulating material 175 surrounding the conductor structures 171. The conductor structures 171 form backside contact pads 172 of the lighting device 100. As is indicated in FIG. 2, the conductor structures 171 may be implemented in the form of a plurality of rewiring planes, or rewiring layers. Correspondingly, the insulating material 175 may be formed as a plurality of insulating layers. The contact structure 170 forms a back side 102 of the lighting device 100, which is opposite to the front side 101.

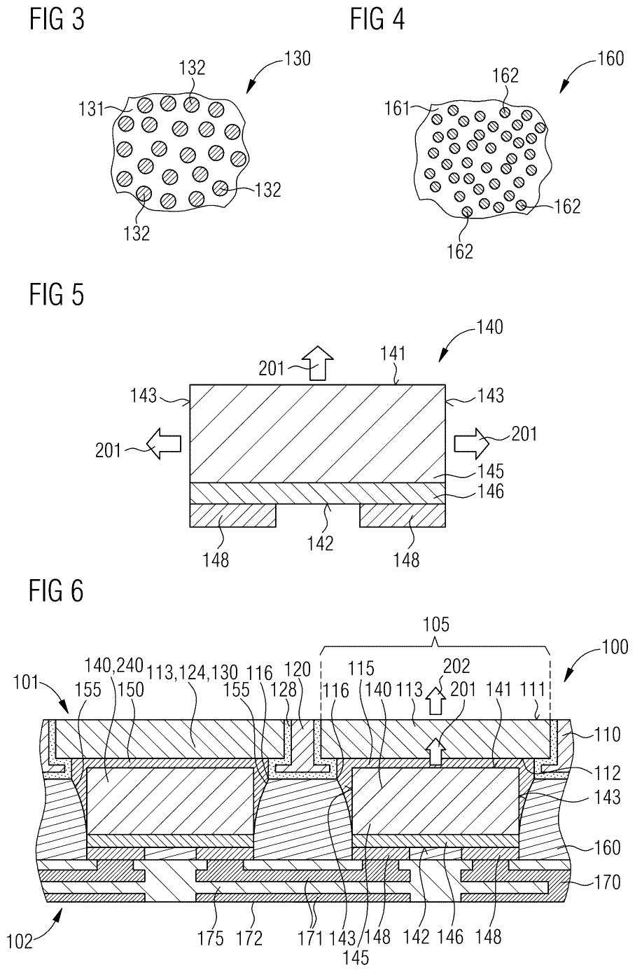

The conversion material 130 contained in the recesses 124 of the carrier 120 comprises, as is depicted in a detail in FIG. 3, a binder material 131 and phosphor particles 132. With the aid of the phosphor particles 132, which may be ceramic phosphor particles, a radiation conversion may be brought about. The phosphor particles 132 may be arranged, or embedded, in the binder material 131. The binder material 131, which may serve as a matrix material, may be a plastic material, or polymer material.

With regard to the reflective stabilization layer 160, a configuration such as is shown in a detail in FIG. 4 may be envisioned. In this case, the stabilization layer 160 comprises a plastic material, or polymer material, 161 and reflective particles 162. The plastic material 161 is, for example, a silicone material. The reflective particles 162 may be arranged, or embedded, in the plastic material 161. With the aid of the reflective particles 162, which may be TiO2 particles, a radiation reflection may be induced.

For the radiation-emitting semiconductor chips 140 of the lighting device 100, a configuration in the form of economical volume emitters is provided. In this configuration, radiation emission during operation of the semiconductor chips 140 may take place through the front side 141 and through the lateral side walls 143. For illustration, FIG. 5 shows a side sectional representation of a single radiation-emitting semiconductor chip 140, a radiation of a light radiation 201 by the front side 141 and by the side walls 143 of the semiconductor chip 140, which takes place during operation of the semiconductor chip 140, being indicated. The light radiation 201 is also referred to below as primary light radiation 201.

Besides the back side contacts 148 already described, the volume-emitting semiconductor chips 140, which are implemented in the form of flip chips, furthermore comprise a frontside radiation-transmissive chip substrate 145 and a backside semiconductor layer sequence 146, which is arranged on the chip substrate 145 and is formed in order to generate radiation. The chip substrate 145 may be a sapphire substrate. The chip substrate 145 forms the front side 141 and a predominant part of the lateral side walls 143 of the respective semiconductor chip 140. Via the backside contacts 148, which are connected to the semiconductor layer sequence 146, the semiconductor layer sequence 146 can be electrically driven in order to bring about the generation of radiation.

During lighting operation of the lighting device 100, individual, several or all of the radiation-emitting semiconductor chips 140 of the emitter group 240 may be electrically driven with the aid of the contact structure 170 of the lighting device 100. In this way, a primary light radiation 201, which can shine through the associated conversion sections 113 of the conversion element 110, may be output by the driven semiconductor chips 140. In the side sectional representation of FIG. 6, which again shows a detail of the lighting device 100, this mode of operation is indicated in relation to a semiconductor chip 140 and therefore a radiation-emitting pixel 105 of the lighting device 100. The primary light radiation 201 may be partially converted by the conversion sections 113 into a secondary light radiation. The primary and secondary light radiation may be output together by the conversion sections 113 in the form of a superimposed mixed radiation 202. The primary and secondary light radiation may be a blue light radiation and a yellow light radiation, so that the pixels 105 of the lighting device 100 may overall emit a white light radiation 202. The light radiation 202 may be output through the front side 101, 111 of the conversion element 110 and of the lighting device 100.

The use of the conversion element 110 having the conversion sections 113 offers the possibility of accurately establishing the position of the light-emitting pixels 105 of the lighting device 100 and the distances between them. The carrier 120 of the conversion element 110, which laterally surrounds the conversion sections 113 in the form of a frame, may bring about optical partitioning between the conversion sections 113 and therefore the pixels 105, so that optical crosstalk between the pixels 105 may be suppressed and a high contrast may be achieved between the pixels 105. Furthermore, thermal energy resulting from the radiation conversion may thereby be dissipated laterally from the conversion sections 113 through the carrier 120 and distributed over the conversion element 110, which enables efficient cooling. The pixelated lighting device 100 may therefore be distinguished by an efficient mode of operation. The reflective stabilization layer 160 likewise contributes to the optical partitioning of the pixels 105 and furthermore gives the lighting device 100 high mechanical stability. Moreover, the stabilization layer 160 enables radiation steering during operation of the lighting device 100. The output coupling mechanism described below plays a part in this.

As has been explained with the aid of FIG. 5, the radiation-emitting semiconductor chips 140 may output the primary light radiation 201 through their front side 141 and lateral side walls 143. The lighting device 100 is formed in such a way that not only can the light radiation 201 output through the front side 141 of the semiconductor chips 140 shine through the conversion sections 113 of the conversion element 110, but in addition the component of the light radiation 201 emitted through the lateral side walls 143 (cf. FIG. 5) can be used efficiently. For the purpose of efficient light output coupling, the configuration described above, and also shown in FIG. 6, of the transparent layer 150 formed for each of the semiconductor chips 140 is used, which comprises in the region of the lateral side walls 143 a layer surface 155 running obliquely and/or curved with respect to the side walls 143. The reflective stabilization layer 160 may therefore likewise have a layer surface running obliquely and/or curved with respect to the lateral side walls 143 of the semiconductor chips 140 in the region of the semiconductor chips 140, and may form reflector structures surrounding the semiconductor chips 140. In this way, with the aid of the stabilization layer 160, a radiation reflection and therefore deviation of the light radiation 201 output through the side walls 143 of the semiconductor chips 140 and coupled into the respectively associated transparent layer 150 may be induced in the direction of the conversion element 110. This radiation component may thereby be supplied to the conversion sections 113 in part by coupling back in, or shining again through the semiconductor chips 140, or their chip substrates 145 (not represented). The reflective stabilization layer 160 may therefore likewise contribute to an efficient mode of operation of the lighting device 100.

FIG. 6 shows a possible configuration in which the conversion element 110, or its carrier 120, is formed in addition with a reflective coating 128. The reflective coating 128 may be a metallic coating. The coating 128 is present in the region of the recesses 124 and indentations 115 of the carrier 120 and of the conversion element 110, and also at the back side of the carrier 120. With the aid of the reflective coating 128, a radiation reflection may be induced in the region of the recesses 124 and indentations 115, which enables an increased luminous efficiency and therefore efficient lighting operation. The front sides 101, 111 of the conversion element 110 and of the lighting device 100 are substantially free from the reflective coating 128. A high contrast may thereby furthermore be ensured between the pixels 105 of the lighting device 100.

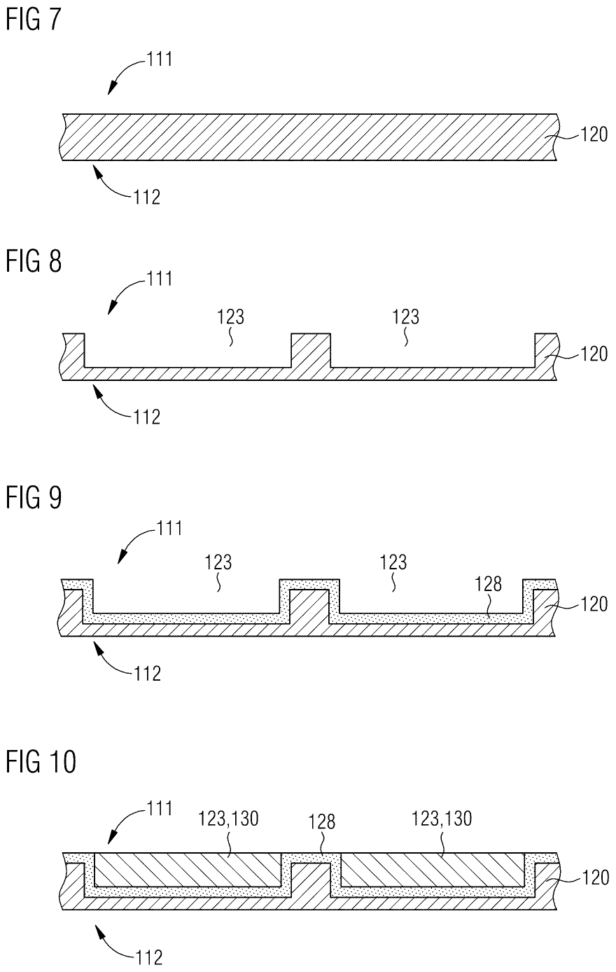

In order to produce the lighting device 100 described above, the method sequence explained below with the aid of FIGS. 7 to 19 may be employed. The production shown in the figures is illustrated with the aid of side sectional representations, corresponding situations respectively being shown in a detail.

FIGS. 7 to 13 show production of the structured conversion element 110 in one possible configuration. At the start, as shown in FIG. 7, a plate-like carrier 120 having two opposite main sides, again referred to below as the front side 111 and back side 112, is provided. The carrier 120 may be a silicon substrate, or silicon wafer. Then, as represented in FIG. 8, cavities 123 are formed in the region of the front side 111 of the carrier 120. For this purpose, an etching process may be carried out by using an etching mask, for example a photoresist mask, formed on the carrier 120 (not represented). The forming of the cavities 123 may take place by deep reactive ion etching (DRIE).

The carrier 120 and its cavities 123 are subsequently provided on the front side with a reflective coating 128, as shown in FIG. 9. The coating 128 may be a metallic coating and may be generated by a corresponding coating method. For example, it is possible to apply a metallic material such as aluminum, silver or gold, for example by sputtering or vapor deposition. Successive application of different metallic materials may furthermore be carried out in order to implement the reflective coating 128 in the form of a metallic layer stack, for example NiAg or NiPdAu.

Following this, as shown in FIG. 10, complete filling of the cavities 123 of the carrier 120 with a conversion material 130 takes place. The conversion material 130 employed may be a binder material, or matrix material, 131 with phosphor particles 132 embedded therein (cf. FIG. 3), and may for example be introduced into the cavities 123 of the carrier 120 by jetting, dosing, or dispensing, or by using a blade (not represented). As an alternative, it is possible initially to fill the cavities 123 of the carrier 120 with pure phosphor particles 132 and subsequently to fix and mechanically stabilize them in the cavities 123 by depositing a binder material 131. For example, aluminum oxide may in this case be deposited by way of atomic layer deposition (ALD).

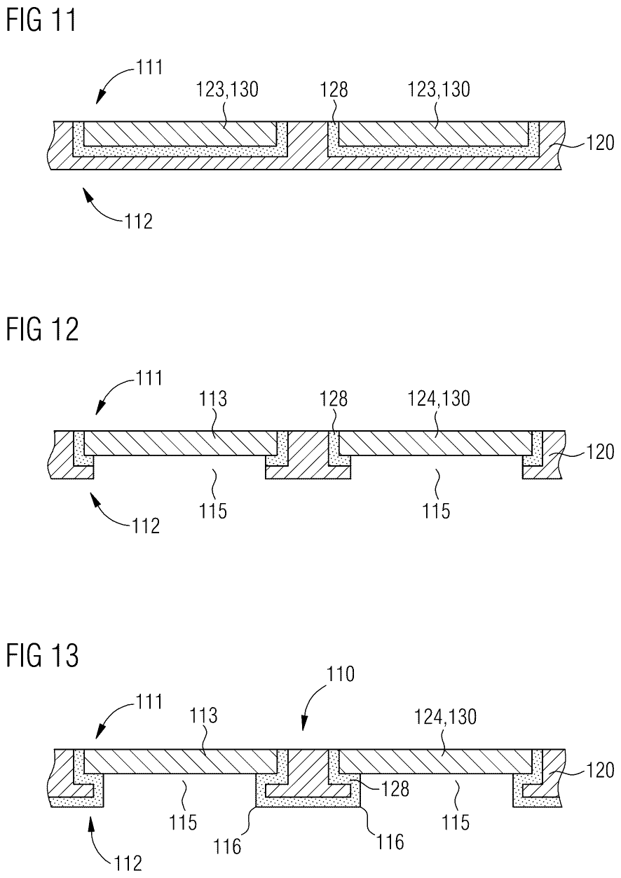

Subsequently, or after curing of the conversion material 130, material removal takes place over a wide area in the region of the front side 111 of the carrier 120, in order to achieve the effect that the front side 111 is substantially free from the reflective coating 128, as represented in FIG. 11. This may be carried out by grinding with the use of a grinding tool. During this process, at least material of the reflective coating 128 and a part of the conversion material 130, as well as optionally original carrier material of the carrier 120 (silicon), are ablated. The material removal may furthermore serve to achieve planarization of the conversion material 130 and of the front side 111.

This is followed by backside material removal, or backside opening of the carrier 120, respectively in the region of the cavities 123, so that the conversion material 130 is exposed at the back side 112 and recesses 124 containing the conversion material 130 result from the cavities 123 of the carrier 120, as shown in FIG. 12, and in this respect conversion sections 113 are formed. In this way, there are furthermore indentations 115 at the back side 112. The backside opening may be carried out by etching, for example deep reactive ion etching, by using an etching mask, or photoresist mask, formed on the carrier 120 (not represented). During this process, at least original carrier material of the carrier 120 and material of the reflective coating 128, as well as optionally a part of the conversion material 130, are removed.

Further processes are subsequently carried out in order to provide the recesses 124 of the carrier 120, of which the recesses 115 form a part, fully with the reflective coating 128 on the inside, as shown in FIG. 13. For this purpose, in a similar way to the procedure explained with the aid of FIG. 9, further coating, or metallic coating, of the carrier 120 takes place, here at the back side 112 of the carrier 120. Since the conversion material 130, or the conversion sections 113, are also coated at the back side during this process and the recesses 124 are thereby closed at the back side with the reflective coating 128 (not represented), backside opening, or removal of the coating 128 in the region of the conversion material 130, is furthermore carried out after the coating method in order to achieve the state illustrated in FIG. 13, and therefore completion of the conversion element 110. For this purpose, etching of the coating 128 may be carried out by using an etching mask, or photoresist mask (not represented). In the conversion element 110 generated in this way, the reflective coating 128 is also present between the recesses 124, or indentations 115, at the back side of the carrier 120. The coated carrier 120 protrudes beyond the conversion material 130 at the back side between the indentations 115. Furthermore, the coated carrier 120 has a shape that encloses the conversion material 130 at the back side 112 in the region of the indentations 115.

Forming of the conversion element 110 with the reflective coating 128, so that the conversion element 110 is present with the configuration shown in FIG. 13 (and also FIG. 6), represents an optional configuration. In contrast thereto, it is possible not to carry out further coating of the carrier 120 after the method state shown in FIG. 12, and in this respect to use the structure shown in FIG. 12 as a conversion element 110, or also to omit forming of the reflective coating 128 entirely.

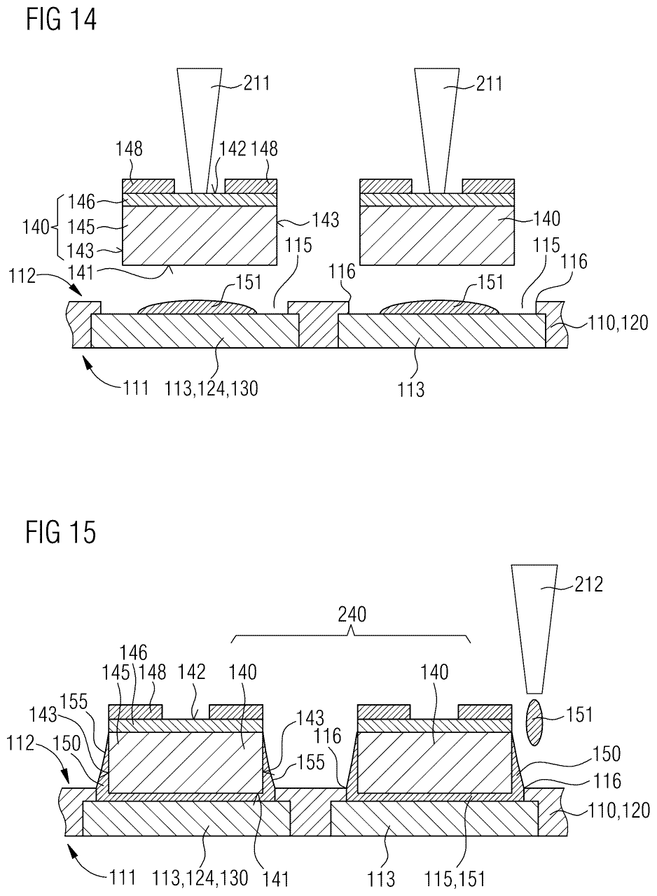

With regard to the variant mentioned last, the coating processes explained with the aid of FIGS. 9 and 13 are obviated and, in contrast to FIG. 10, the conversion material 130 is introduced into the cavities 123 of the uncoated carrier 120. The frontside material ablation explained with the aid of FIG. 11 may be obviated or carried out with the aim of planarizing the conversion material 130 and the front side 111 of the carrier 120. The conversion element 110 generated in this way may thereby have a configuration such as is shown in FIG. 2. For reasons of clarity, a simplified representation corresponding to FIG. 2 of the conversion element 110 without a reflective coating 128 is selected in FIGS. 14 to 19, with the aid of which the further production of the lighting device 100 is described. The conversion element 110 may in this case have a configuration without or with a coating 128.

FIGS. 14 to 19 show the further method sequence for the production of the lighting device 100 in one possible configuration. After the providing of the conversion element 110, as shown in FIGS. 14 and 15, forming of an emitter group 240 of radiation-emitting semiconductor chips 140 takes place at the back side 112 of the conversion element 110, a semiconductor chip 140 respectively being provided in the region of the conversion sections 113 and indentations 115 of the conversion element 110. In the method sequence described here, the radiation-emitting semiconductor chips 140 are provided and subsequently mounted on the conversion element 110 by way of adhesive bonding. In this way, the possibility of testing and/or presorting the semiconductor chips 140 is available before they are mounted, so that productivity losses may be avoided and the lighting device 100 may be produced according to established specifications with regard to the radiation emission.

The radiation-emitting semiconductor chips 140, which have smaller lateral dimensions than the indentations 115 of the conversion element 110, are arranged centrally in the region of the indentations 115 of the conversion element 110 by using a transparent adhesive material 151 while being partially, or to a small extent, received in the indentations 115. The adhesive material 151 may be a transparent sapphire adhesive or silicone adhesive. As shown in FIGS. 14 and 15, the adhesive material 151 may initially be applied respectively inside the indentations 115 on the conversion element 110, or the conversion material 130 present there, and the radiation-emitting semiconductor chips may then be placed inside, or in the region of, the indentations 115 and put on the adhesive material 151. This is done in an orientation of the semiconductor chips 140 in which the front side 141, or the frontside chip substrate 145, of the semiconductor chips 140 faces toward the back side 112 of the conversion element 110. The placement of the semiconductor chips 140 may be carried out with the aid of a placing tool, corresponding suction nozzles 211 of which are depicted in FIGS. 14 and 15. The semiconductor chips 140 may in this case be held on their back side 142 by using a negative pressure by way of the suction nozzles 211. It is possible to arrange several or all of the semiconductor chips 140 on the conversion element 110 with the aid of the placing tool.

The light-emitting semiconductor chips 140 are placed and put on the adhesive material 151 with a corresponding application pressure and therefore while displacing and laterally pressing out the adhesive material 151, so that wetting of the lateral side walls 143 of the semiconductor chips 140 with the adhesive material 151 can be induced, as is shown in FIG. 15. During this process, the indentations 115 of the conversion element 110, or a circumferential edge thereof, act as a stop edge 116 for the adhesive material 151 wetting the side walls 143 of the semiconductor chips 140, so that the adhesive material 151 does not emerge laterally beyond the indentations 115 but remains localized in the region of the indentations 115 and of the semiconductor chips 140 arranged there. For each of the semiconductor chips 140, the adhesive material 151 may thereby form in a self-aligned manner a transparent layer 150 which adjoins a semiconductor chip 140 in the region of the front side 141 and of the side walls 143 and comprises in the region of the side walls 143 a layer surface 155 running curved and/or obliquely with respect to the side walls 143. The transparent layer 150 furthermore adjoins the back side of the conversion element 110 in the region of a corresponding indentation 115. The layer 150 covering the side walls 143 of a semiconductor chip 140 may also be referred to as a chip fillet, side fillet, adhesive fillet or output coupling fillet. In a coated configuration of the carrier 120 of the conversion element 110, the wetting stop edge 116 may be formed by the reflective coating 128, and in an uncoated configuration of the carrier 120, the wetting stop edge 116 may be formed by original carrier material of the carrier 120 (silicon) (cf. FIGS. 6, 13 and 15).

Depending on parameters such as the amount of adhesive material 151 used, after the placement of the radiation-emitting semiconductor chips 140 it is furthermore conceivable optionally to carry out additional application of the adhesive material 151 in the region of the lateral side walls 143 of the semiconductor chips 140, in order to wet the side walls 143 sufficiently with the adhesive material 151. This may take place with the aid of a dosing device, or a dispenser, a corresponding dosing nozzle 212 of which is represented in FIG. 15. The dosing of the additional adhesive material 151 takes place close to the side walls 143 of the semiconductor chips 140. During this process as well, the indentations 115 of the conversion element 110 form a stop edge 116 for the adhesive material 151 so that the adhesive material 151 does not emerge laterally beyond the indentations 115, and in this respect self-aligned generation of the transparent layer 150 having the layer surface 155 running curved and/or obliquely with respect to the side walls 143 may be achieved.

In contrast to FIGS. 14 and 15, it is possible to provide the radiation-emitting semiconductor chips 140 with the adhesive material 151 on their front side 141 and to place the semiconductor chips 140 prepared in this way inside, or in the region of, the indentations 115 of the conversion element 110 with the aid of the placing tool (not represented). In this way as well, displacement of the adhesive material 151 and wetting of the lateral side walls 143 of the semiconductor chips 140 with the adhesive material 151 may be brought about so that the adhesive material 151, as described above, can form in a self-aligned manner a transparent layer 150 for each of the semiconductor chips 140, which adjoins a semiconductor chip 140 in the region of the front side 141 and of the side walls 143 and has a layer surface 155 running curved and/or obliquely with respect to the side walls 143. During this procedure as well, additional application of the adhesive material 151 may optionally take place in the region of the side walls 153 of the semiconductor chips 140 after the placement of the semiconductor chips 140.

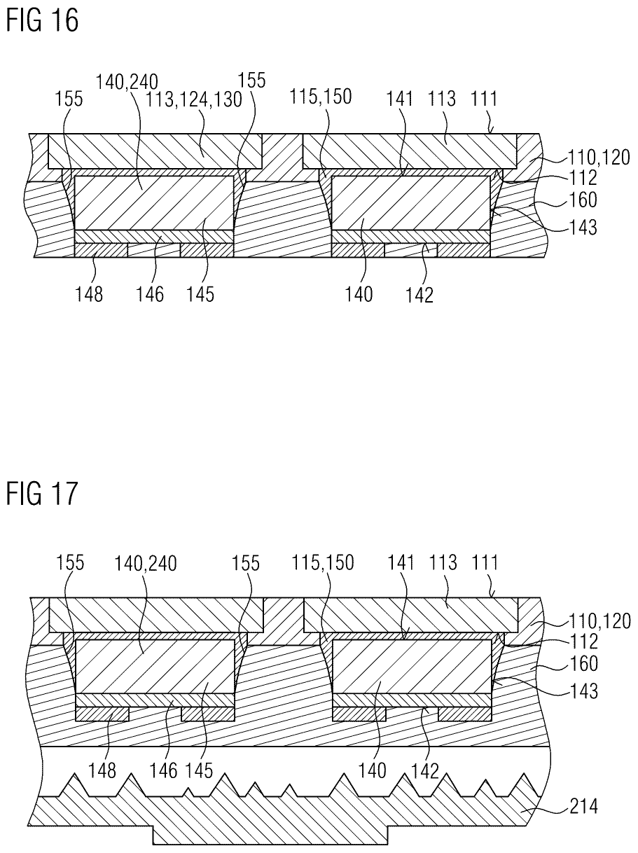

After the forming of the emitter group 240 of radiation-emitting semiconductor chips 140 on the conversion element 110 and forming of the transparent layers 150, or after curing thereof, as represented in FIG. 16, forming of a reflective stabilization layer 160 takes place in the region of the back side 112 of the conversion element 110 while framing the semiconductor chips 140. The stabilization layer 160 is located laterally with respect to and between the semiconductor chips 140, and is also present at the back side of the semiconductor chips 140. The stabilization layer 160 adjoins the transparent layers 150 present in the region of the semiconductor chips 140 and, as described above, forms reflector structures surrounding the radiation-emitting semiconductor chips 140 because of the layer surface 155 of the transparent layers 150 running curved and/or obliquely with respect to the side walls 143 of the semiconductor chips 140. The stabilization layer 160 also adjoins the back side of the conversion element 110, or its carrier 120. According to FIG. 16, the stabilization layer 160 is generated in such a way that backside surfaces of the contacts 148 of the semiconductor chips 140 are free from the stabilization layer 160 and the stabilization layer 160 ends flush with the backside faces of the contacts 148.

For the forming of the stabilization layer 160, a plastic material 161 with reflective particles 162 embedded therein (cf. FIG. 4) may be applied on the conversion element 110 carrying the emitter group 240 of radiation-emitting semiconductor chips 140. For this purpose, a molding process may be carried out by using a molding tool. It is also possible to cast plastic material 161 containing reflective particles 162, which may take place by using a boundary structure referred to as a dam. Such a process is also referred to as a dam-and-fill method (not represented in each case). The stabilization layer 160 may subsequently cure, or be cured.

As is depicted in FIG. 17, there is the possibility of generating the stabilization layer 160 in a manner such that the stabilization layer 160 protrudes at the back side beyond the contacts 148 of the radiation-emitting semiconductor chips 140 and the contacts 148 are covered by the stabilization layer 160. In such a case, a part of the stabilization layer 160 may be removed in order to provide a state corresponding to FIG. 16. This may be carried out by grinding, or grinding back, by using a grinding tool 214, as is indicated in FIG. 17.

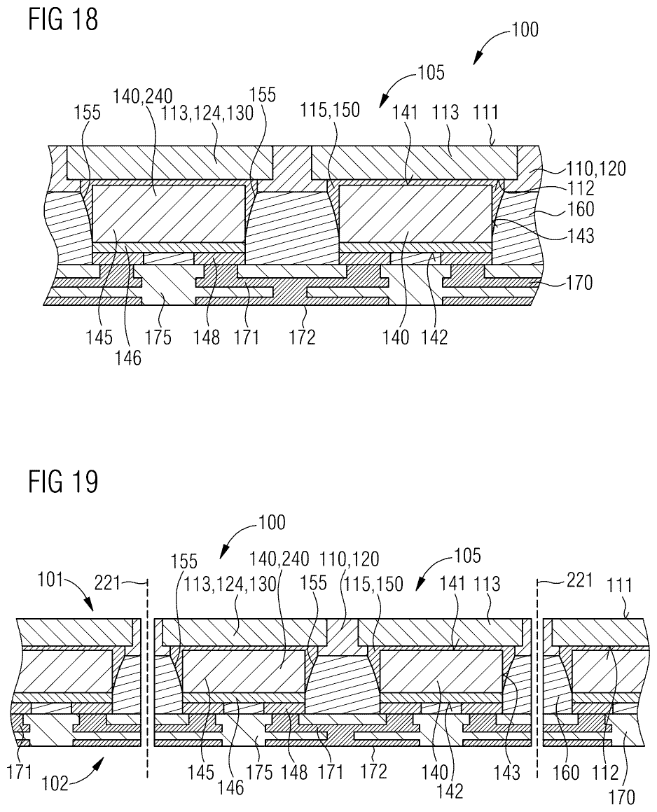

Following this, as shown in FIG. 18, a contact structure 170 is formed in the region of the back side 142 of the radiation-emitting semiconductor chips 140, which faces away from the conversion element 110. The backside contact structure 170 adjoins the stabilization layer 160 and the contacts 148 of the radiation-emitting semiconductor chips 140. The contact structure 170 comprises metallic conductor structures 171, which are electrically connected to the contacts 148 of the semiconductor chips 140, and an electrically insulating material 175, which surrounds the conductor structures 171. The conductor structures 171 form backside contact pads 172, via which the lighting device 100 can be contacted and electrically supplied in order to drive the semiconductor chips 140.

The contact structure 170 may, as indicated in FIG. 18, be implemented in the form of a fan-out multistack so that the conductor structures 171 form a plurality of interconnection planes, or rewiring planes. In this configuration, the contact structure 170 may for example be implemented in the form of a multilayer printed circuit board (PCB), which may be mounted on the stabilization layer 160 and the contacts 148 of the semiconductor chips 140 by way of adhesive bonding and/or soldering. The contact structure 170 may, as an alternative, be produced on the stabilization layer 160 and the contacts 148 of the semiconductor chips 140 by successive application of an insulating material, or dielectric material, and a metallic material, together with corresponding structuring steps and opening steps. With regard to the metallic material, the application may be electroplating.

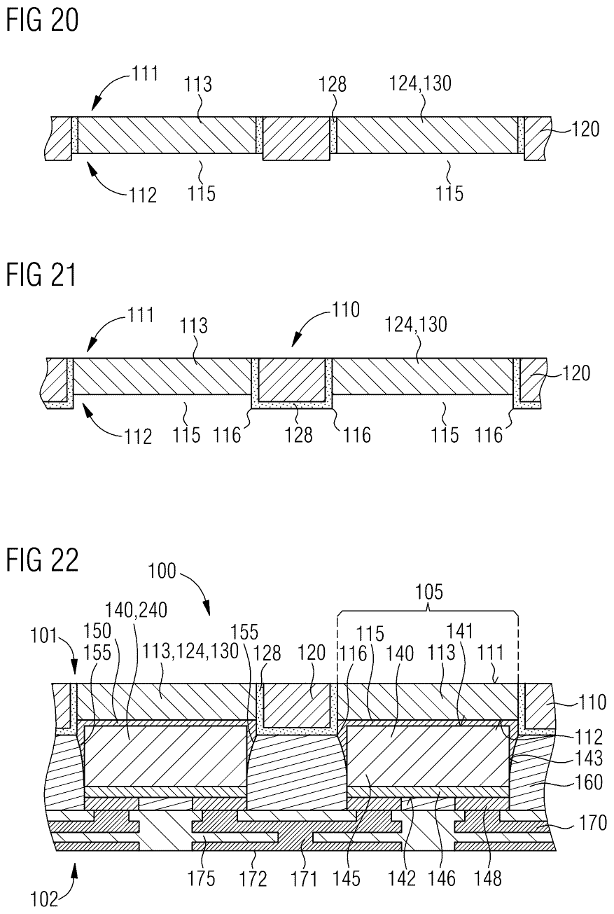

The lighting device 100 may be completed by the forming of the contact structure 170. In this respect, the finished lighting device 100 may be depicted in FIG. 18. The method may, however, also be carried out in a manner such that a plurality of lighting devices 100 are produced together. For this purpose, the conversion element 110 may be provided with lateral dimensions and a number of conversion sections 113 for a plurality of lighting devices 100, that is to say in the form of a conversion element panel or conversion element wafer, and a panel consisting of a plurality of contiguous lighting devices 100 may be manufactured by the steps described above, such as the forming of the emitter group 240 with the radiation-emitting semiconductor chips 140 on the conversion element 110, the forming of the stabilization layer 160 and the generation of the contact structure 170. In this variant, as shown in FIG. 19, the panel may then be singulated into a plurality of lighting devices 100 in order to provide them in a separate form. In this case, the panel is cut between conversion sections 113 and semiconductor chips 140, as is indicated in FIG. 19 with the aid of partitioning lines 221. During this process, the conversion element 110, or its carrier 120, the stabilization layer 160 and the contact structure 170 are cut and thereby separated between a plurality of lighting devices 100. A sawing process may be carried out for the singulation.

The providing of the conversion element 110 having the conversion sections 113 and forming of the emitter group 240 of radiation-emitting semiconductor chips 140 on the conversion element 110, which are carried out during the method, make it possible to establish the respective position of the pixels 105 of the lighting device and the distances between the pixels 105 with high accuracy. The lighting device 100 may thereby be produced in a manner such that there are constant and also relatively small distances between the pixels 105, which makes seamless illumination possible during operation of the lighting device 100.

The forming of the backside contact structure 170 represents an optional configuration. In contrast thereto, it is possible not to form such a contact structure 170 and instead to use the contacts 148 of the radiation-emitting semiconductor chips 140 themselves as contacts, or contact pads, for the contacting and electrical supply of the lighting device 100. Accordingly, FIG. 16 may show a configuration of the lighting device 100 implemented in this sense. In this variant as well, combined production of a plurality of lighting devices 100 is conceivable, and in this respect singulation of the panel produced according to FIG. 16 into separate lighting devices 100 may be carried out after the forming of the stabilization layer 160.

Further possible variants and configurations, which may be envisioned in relation to the lighting device 100 and the associated production method, are described below. Matching features and details, as well as components, which are the same and have the same effect, are not described in detail again below. For details in this regard, reference is instead made to the description above.

FIGS. 20 to 22 show the production of the lighting device 100 according to a further configuration in a detail with the aid of side sectional representations. In this case, the manufacture of the conversion element 110 initially takes place according to FIGS. 7 to 11. As is represented in FIGS. 20 and 21, in contrast to FIGS. 12 and 13, the backside opening of the carrier 120 in the region of the cavities 123 and the following further backside coating of the carrier 120 and opening of the reflective coating 128 in the region of the conversion material 130 take place in a manner such that the coated carrier 120 does not have a shape that encloses the conversion material 130 at the back side 112 in the region of the indentations 115. The conversion element 110, as shown in FIG. 21, in comparison with the configuration depicted in FIG. 13, thereby comprises recesses 124 with cross-sectionally straight instead of stepped inner sides, and a laterally set-back stop edge 116 in the region of the indentations 115. The further method sequence for the completion of the lighting device 100 depicted in FIG. 22 takes place in the manner described above by forming the emitter group 240 of radiation-emitting semiconductor chips 140 on the conversion element 110, forming the stabilization layer 160, forming the contact structure 170 and optionally carrying out singulation.

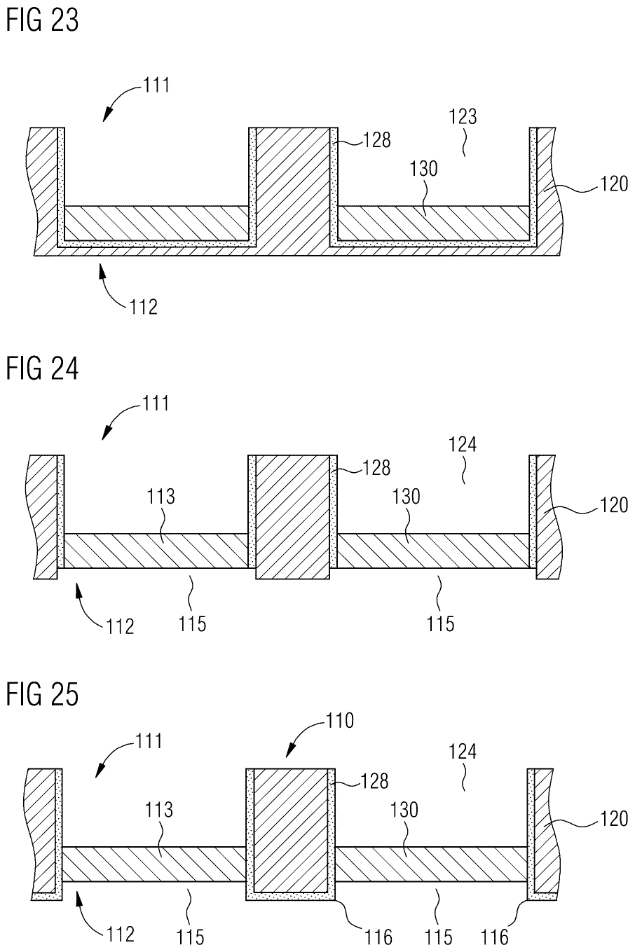

FIGS. 23 to 26 show the production of the lighting device 100 according to a further configuration in a detail with the aid of side sectional representations. The manufacture of the conversion element 110 initially takes place according to FIGS. 7 to 9. However, the introduction of the conversion material 130 into the cavities 123 of the carrier 120 is carried out in such a way that, as shown in FIG. 23, the cavities 123 are only partially filled with the conversion material 130. The conversion material 130 is in this case located in a lower partial region, or bottom-side partial region, of the cavities 123, and a remaining partial region, or frontside partial region, of the cavities 123 is free from the conversion material 130. In relation to this variant, in comparison with the configurations described above, it is conceivable to provide the carrier 120 with a larger thickness and to implement the cavities 123 of the carrier 120 with a larger depth extent. Material removal, or grinding, in order to remove the reflective coating 128 in the region of the front side 111 of the carrier 120 may be carried out after the introduction of the conversion material 130 into the cavities 123, or before this.

As is represented in FIGS. 24 and 25, the backside opening of the carrier 120 in the region of the cavities 123 and the following further backside coating of the carrier 120 and backside removal of the reflective coating 128 in the region of the conversion material 130 subsequently take place. According to the configuration shown here, these steps are carried out according to FIGS. 20 and 21. In this way, the coated carrier 120 of the conversion element 110 depicted in FIG. 25 does not have a shape that encloses the conversion material 130 in the region of the indentations 115. A procedure (not represented) corresponding to FIGS. 12 and 13 is, however, also possible.

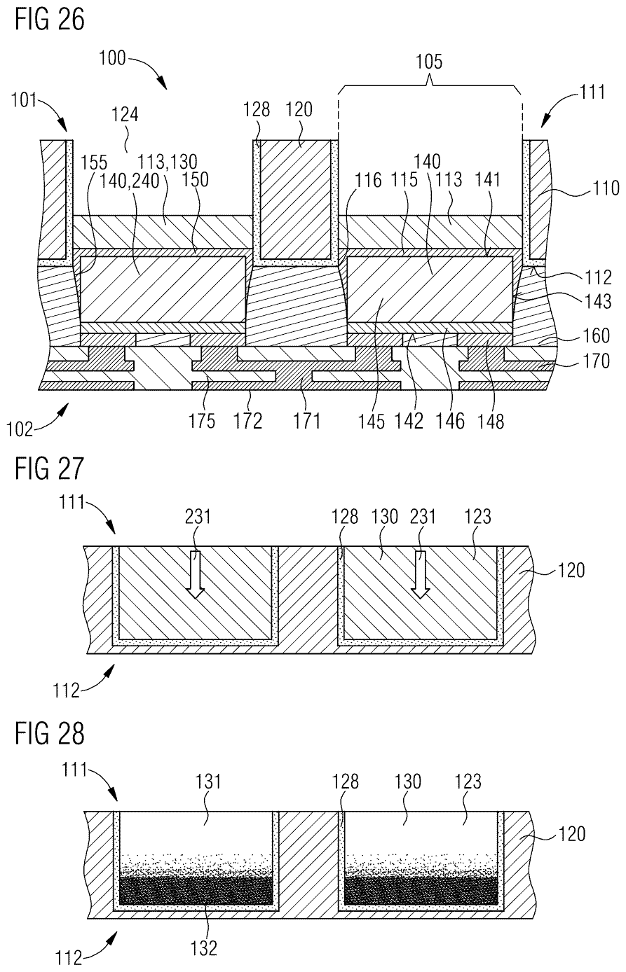

In order to complete the lighting device 100 represented in FIG. 26, the procedure as described above is subsequently adopted, i.e. forming the emitter group 240 of radiation-emitting semiconductor chips 140 on the conversion element 110, forming the stabilization layer 160, forming the contact structure 170 and optionally carrying out singulation. The partial filling of the cavities 123 of the carrier 120 has the effect that the recesses 124 of the carrier 120 of the conversion element 110, which result from the cavities 123, are free from the conversion material 130 in a frontside partial region, or emission-side partial region. Beam guiding, or beamforming, may be achieved in this partial region during lighting operation of the lighting device 100. The recesses 124 of the carrier 120 which are provided with the reflective coating 128 may in this case act as a beam tube for directing the light radiation emitted by the pixels 105 forward.

FIGS. 27 to 29 show the production of the lighting device 100 according to a further configuration in a detail with the aid of side sectional representations. The manufacture of the conversion element 110 is initially performed according to FIGS. 7 to 11, so that, as shown in FIG. 27, the cavities 123 of the carrier 120 are fully filled with the conversion material 130. The conversion material 130 employed is a binder material, or matrix material, 131 containing phosphor particles 132 (cf. FIG. 3), which as described above may be introduced into the cavities 123 of the carrier 120 as described above by jetting, dispensing or by using a blade. In this configuration as well, a larger thickness may be provided for the carrier 120 and a greater depth extent may be provided for its cavities 123.

As is represented in FIGS. 27 and 28, sedimentation furthermore takes place so that the phosphor particles 132 settle in the direction of the bottom, or a bottom face, of the cavities 123. In FIG. 27, a force action 231 that induces the sedimentation is indicated with the aid of arrows. The sedimentation may be brought about by the influence of weight over time, or by centrifuging. In this way, the conversion material 130 may have a density of phosphor particles 132 which increases in the direction of the bottom of the cavities 123. The phosphor particles 132 may in this case be concentrated in the region of the bottom of the cavities 123, there may be only the matrix material, or substantially only the matrix material 131, and no phosphor particles, or substantially no phosphor particles 132, in a frontside partial region of the cavities 123, and there may be a transition, or gradual transition, in relation to the size and density of the phosphor particles 132.

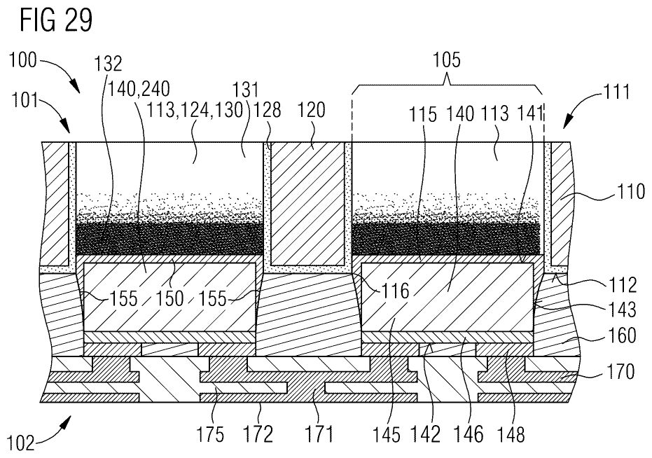

The further method sequence for the completion of the lighting device 100 depicted in FIG. 29 takes place in the manner described above. In this case, the conversion element 110 is initially generated by performing the backside opening of the carrier 120 in the region of the cavities 123 and the following further backside coating of the carrier 120 and backside removal of the reflective coating 128 in the region of the conversion material 130. In the present case, these steps are carried out according to FIGS. 20 and 21, so that the carrier 120 of the conversion element 110, as shown in FIG. 29, does not have a shape that encloses the conversion material 130 in the region of the indentations 115. A procedure (not represented) corresponding to FIGS. 12 and 13 is, however, also possible. Subsequently, steps such as forming the emitter group 240 of radiation-emitting semiconductor chips 140 on the conversion element 110, forming the stabilization layer 160, forming the contact structure 170 and optionally carrying out singulation take place. The sedimentation has the effect that the recesses 124 of the carrier 120 of the conversion element 110, which result from the cavities 123, comprise only the matrix material, or substantially only the matrix material 131, and no phosphor particles, or substantially no phosphor particles 132, in a frontside partial region, or emission-side partial region, so that beam guiding, or beamforming, may be achieved in this partial region during lighting operation of the lighting device 100. In this case as well, the recesses 124 of the carrier 120 which are provided with the reflective coating 128 may act as a beam tube for directing the emitted light radiation forward. The phosphor particles 132 which bring about the radiation conversion are concentrated in a backside partial region of the recesses 124 of the carrier. There may be a varying density of the phosphor particles 132 between the frontside partial region and the backside partial region of the recesses 124.

A modification of the method explained with the aid of FIGS. 27 to 29 consists in only partially filling the cavities 123 of the carrier 120 with the conversion material 130 (not represented).

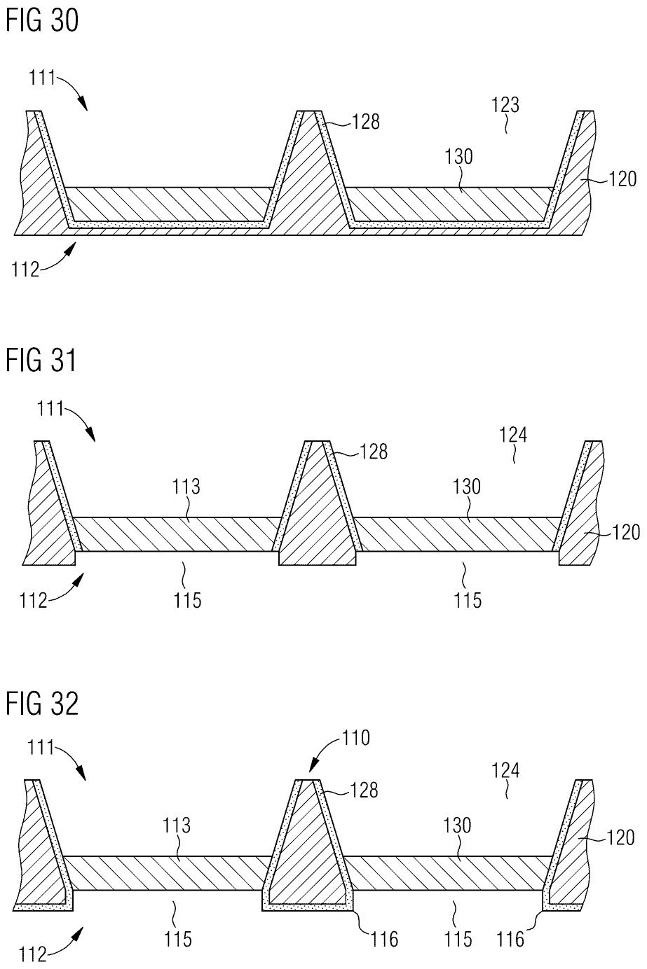

FIGS. 30 to 33 show the production of the lighting device 100 according to a further configuration in a detail with the aid of side sectional representations. The manufacture of the conversion element 110 initially takes place in a similar way to FIGS. 7 to 11, the cavities 123 of the carrier 120 being generated in such a way that the cavities 123, as represented in FIG. 30, comprise side walls running not perpendicularly but instead obliquely with respect to a bottom face. In this case, the cavities 123 have a cross-sectional shape which broadens in a direction away from the bottom face. The introduction of the conversion material 130 into the cavities 123 is furthermore carried out according to FIG. 23, so that the cavities 123, as shown in FIG. 30, are only partially filled with the conversion material 130. In this configuration as well, a larger thickness may be provided for the carrier 120 and a greater depth extent may be provided for its cavities 123. Material removal in order to remove the reflective coating 128 in the region of the front side 111 of the carrier 120 may be carried out after the introducing of the conversion material 130 into the cavities 123, or before this.

As is represented in FIGS. 31 and 32, the backside opening of the carrier 120 in the region of the cavities 123 and the following further backside coating of the carrier 120 and backside removal of the reflective coating 128 in the region of the conversion material 130 subsequently take place. In the present case, these steps are carried out according to FIGS. 20 and 21, so that the carrier 120 of the conversion element 110, as shown in FIG. 32, does not have a shape that encloses the conversion material 130 in the region of the indentations 115. A procedure (not represented) corresponding to FIGS. 12 and 13 is, however, also possible. In the conversion element 110 generated in this way, the recesses 124 of the carrier 120 which result from the cavities 123, except for the region of the indentations 115, have a cross-sectional shape which broadens in a direction away from the indentations 115.

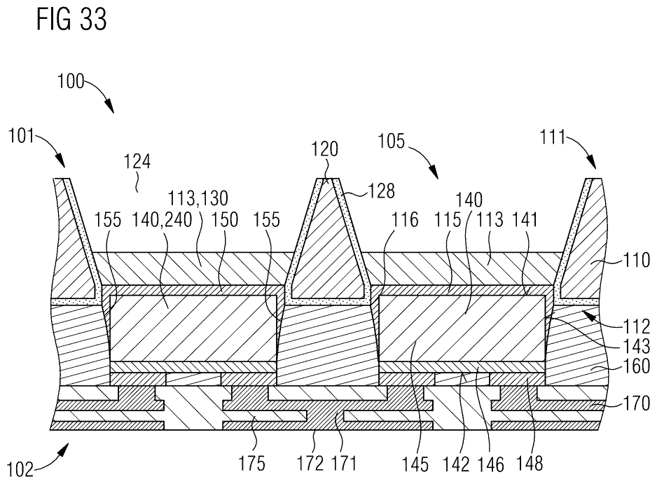

In order to complete the lighting device 100 represented in FIG. 33, the procedure as described above is then adopted, i.e. forming the emitter group 240 of radiation-emitting semiconductor chips 140 on the conversion element 110, forming the stabilization layer 160, forming the contact structure 170 and optionally carrying out singulation. In this configuration, the recesses 124 of the carrier 120 of the conversion element 110, which widen in a direction away from the radiation-emitting semiconductor chips 140 and are provided with the reflective coating 128, may serve as reflector structures, with the aid of which beamforming may be achieved during lighting operation of the lighting device 100.

A modification of the method explained with the aid of FIGS. 30 to 33 consists in fully filling the cavities 123 of the carrier 120 with the conversion material 130 and/or sedimentation of phosphor particles 132 taking place (not represented).

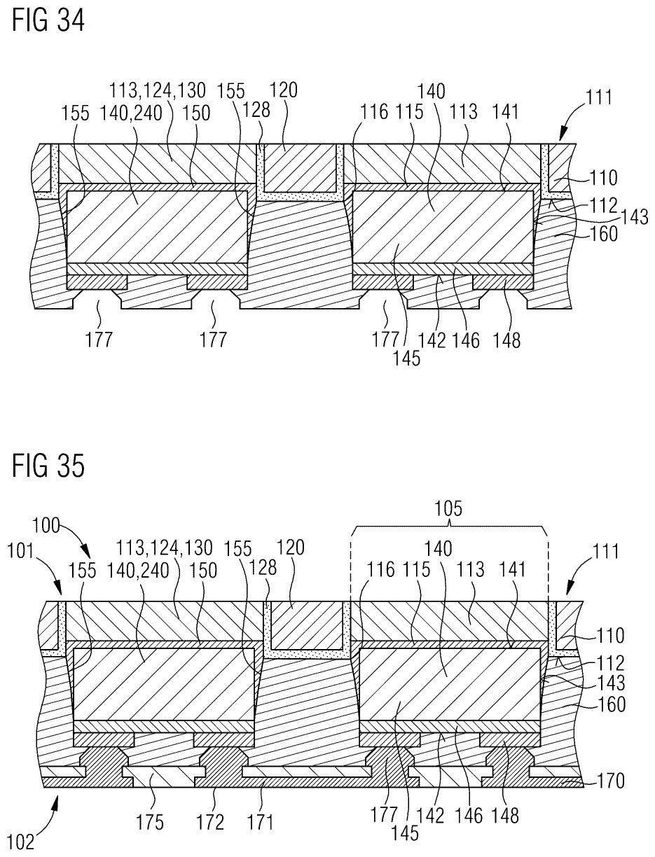

FIGS. 34 and 35 show the production of the lighting device 100 with a further configuration of the contact structure 170 in a detail with the aid of side sectional representations. In this case, the stabilization layer 160 is generated in a manner corresponding to FIG. 17 so that the stabilization layer 160 protrudes at the back side beyond the contacts 148 of the radiation-emitting semiconductor chips 140 and covers them. Instead of grinding back, backside removal of the material of the stabilization layer 160 is carried out in the region of the contacts 148 so that, as shown in FIG. 34, openings 177 which reach as far as the contacts 148 are formed in the stabilization layer 160. Subsequently, the backside contact structure 170 adjoining the stabilization layer 160 and the contacts 148 of the semiconductor chips 140 is formed. The contact structure 170 comprises metallic contact structures 171, which are electrically connected to the contacts 148 and are partly present in the openings 177, and an electrically insulating material 175, which surrounds the conductor structures 171. The conductor structures 171 form backside contact pads 172 of the lighting device 100. The contact structure 170 may be produced by successive application of a metallic material and a dielectric material, together with corresponding structuring steps. The insulating material 175, which serves as passivation, may also be omitted so that the conductor structures 171 may adjoin only the stabilization layer 160 and the contacts 148. A configuration of the contact structure 170 which corresponds to FIG. 35 may also be envisioned for the designs of the lighting device 100 which are described above and below.

The forming of the emitter group 240 of radiation-emitting semiconductor chips 140 on the conversion element 110 may be carried out not only by mounting separate semiconductor chips 140 but also monolithically, that is to say at the wafer level, by using a wafer 242. Possible configurations are explained in more detail below.

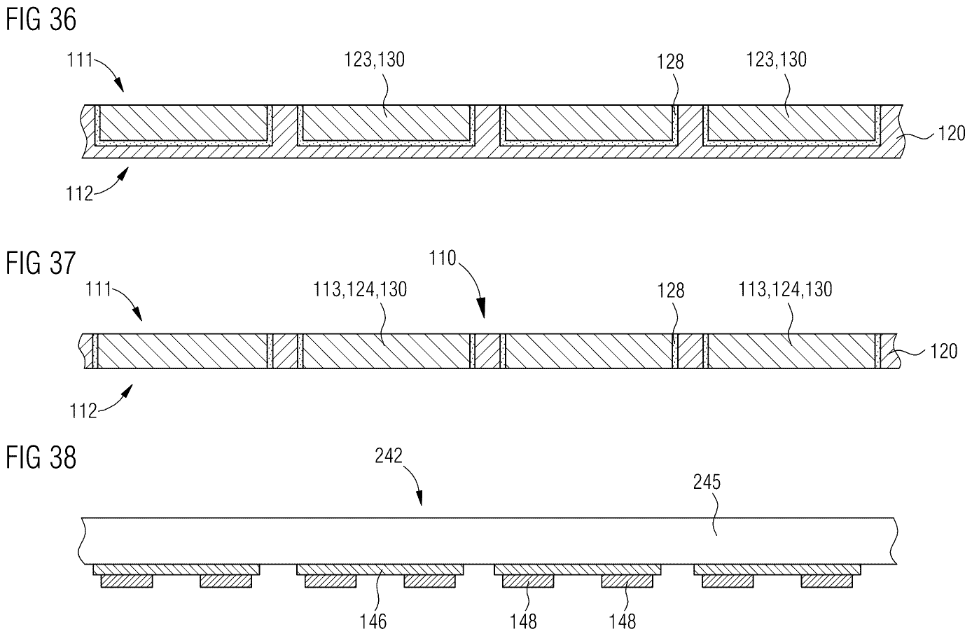

FIGS. 36 to 42 show the production of the lighting device 100 according to a further configuration in a detail with the aid of side sectional representations. The conversion element 110 employed here may again be a conversion element panel, or conversion element wafer, for a plurality of lighting devices 100, and may be divided between a plurality of lighting devices 100 during singulation carried out at the end of the method. In order to manufacture the conversion element 110, the procedure corresponding to FIGS. 7 to 11 is initially adopted, so that the carrier 120 with the configuration shown in FIG. 36 is provided. On the basis of this, however, selective material removal is not carried out in the region of the cavities 123 of the carrier 120 which contain conversion material 130. Instead, material removal takes place over a wide area at the back side 112 of the carrier 120, for example by grinding by way of a grinding tool. The conversion material 130 is thereby exposed at the back side 112, as shown in FIG. 37, recesses 124 containing conversion material 130 result from the cavities 123 of the carrier 120 and in this respect conversion sections 113 are formed. During this process, at least original carrier material of the carrier 120 (silicon) and material of the reflective coating 128, as well as optionally a part of the conversion material 130, are removed. In the conversion element 110 generated in this way, the back side 112 is planar. The carrier 120 of the conversion element 110 also has recesses 124 with cross-sectionally straight inner sides. The reflective coating 128 is present only on the inside of the recesses 124.

In the present method sequence, instead of separate radiation-emitting semiconductor chips 140, an unsingulated wafer 242 is provided and arranged on the conversion element 110. As shown in FIG. 38, the wafer 242 comprises a frontside radiation-transmissive substrate 245, separate semiconductor layer sequences 146, which are arranged next to one another at the back side of the radiation-transmissive substrate 245 and are formed in order to generate radiation, and backside contacts 148 which are connected to the semiconductor layer sequences 146. The substrate 245 may be a sapphire substrate. Via the contacts 148, the semiconductor layer sequences 146 can be electrically driven in order to generate radiation. The semiconductor layer sequences 148 may match the conversion sections 113 of the conversion element 110 in respect of the lateral dimensions.

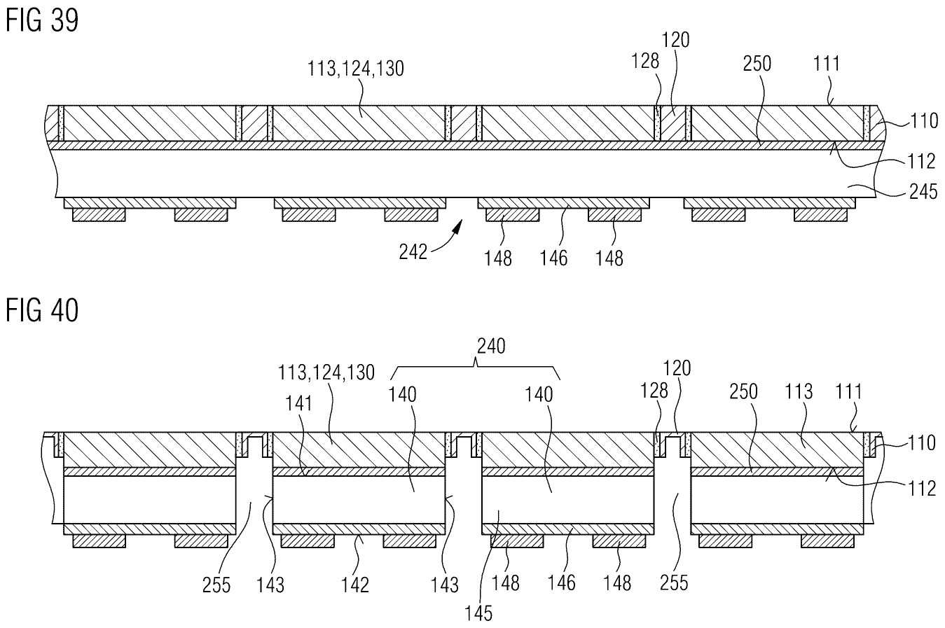

In order to arrange the wafer 242 on the conversion element 110, as depicted in FIG. 39, the wafer 242 is connected with its substrate 245 via a transparent connecting material 250 to the conversion element 110, or to the back side 112 of the conversion element 110. In order to connect the wafer 242 and the conversion element 110, a wafer bonding method or adhesive bonding may be carried out. The connecting material 250 may be a transparent adhesive material, for example a silicone adhesive. The wafer 242 and the conversion element 110 are brought together in such a way that, as seen in a plan view of the wafer 242 and the conversion element 110, the semiconductor layer sequences 146 are each located in the region of a conversion section 113 of the conversion element 110.

Then, as is shown in FIG. 40, the wafer 242 is cut starting from its back side so that an emitter group 240 of singulated radiation-emitting semiconductor chips 140, which is arranged on the conversion element 110 at the back side 112, is provided. The cutting of the wafer 242 may be carried out mechanically, for example by sawing. The cutting forms partitioning trenches 255, which are located between the semiconductor chips 140 and separate them from one another. The partitioning trenches 255 may laterally surround the semiconductor chips 140 and be in the form of a continuous trench structure, which has the shape of a grid in plan view. As is represented in FIG. 40, the cutting takes place in a manner such that material of the wafer 242, a part of the connecting material 250 and material of the conversion element 110 are removed. With regard to the wafer 242, the material removal relates to the substrate 245 and optionally the semiconductor layer sequences 146 on their lateral sides. With regard to the conversion element 110, material of the reflective coating 128, original carrier material of the carrier 120 (silicon), as well as optionally a part of the conversion material 130, are removed. As is furthermore shown in FIG. 40, the cutting may take place in multiple stages so that the partitioning trenches 255 may have a stepped shape in cross section.

The radiation-emitting semiconductor chips 140 formed by the cutting of the wafer 242 are volume emitters which comprise a frontside radiation-transmissive chip substrate 145 resulting from the substrate 245, a backside semiconductor layer sequence 146 for generating radiation, which is arranged on the chip substrate 145, and backside contacts 148. There is therefore a construction corresponding to FIG. 5. The semiconductor chips 140 are connected via the connecting material 250 to the conversion element 110, or to its conversion material 130, and are oriented in such a way that the front side 141 of the semiconductor chips 140 faces toward the conversion element 110 and the opposite back side 142 faces away from the conversion element 110. The cutting may take place in such a way that the lateral dimensions of the semiconductor chips 140, as shown in FIG. 40 and therefore in contrast to FIG. 1, match the lateral dimensions of the recesses 124 of the carrier 120 of the conversion element 110 and of the conversion sections 113.

Subsequently, as shown in FIG. 41, further coating, or metallic coating, of the conversion element 110 carrying the emitter group 240 of radiation-emitting semiconductor chips 140 and forming of a stabilization layer 160 take place. By the coating, the reflective coating 128 is additionally formed on the semiconductor chips 140, or on their back sides 142, contacts 148 and lateral side walls 143, and also on the conversion element 110 between the semiconductor chips 140. In order to avoid a possible occurrence of a short circuit because of the reflective coating 128, an insulating layer or dielectric layer, on which the reflective coating 128 may be formed, may optionally be formed beforehand in the region of the semiconductor layer sequences 146 and contacts 148 of the semiconductor chips 140 (not represented).

The stabilization layer 160 is then formed in such a way that the stabilization layer 160 is located inside the partitioning trenches 255 and therefore laterally with respect to and between the semiconductor chips 140, and is also present at the back side of the semiconductor chips 140 and protrudes beyond the semiconductor chips 140 at the back side. The stabilization layer 160 adjoins the reflective coating 128. The generation of the stabilization layer 160 may, as described above, be performed by carrying out a molding process or by way of casting.

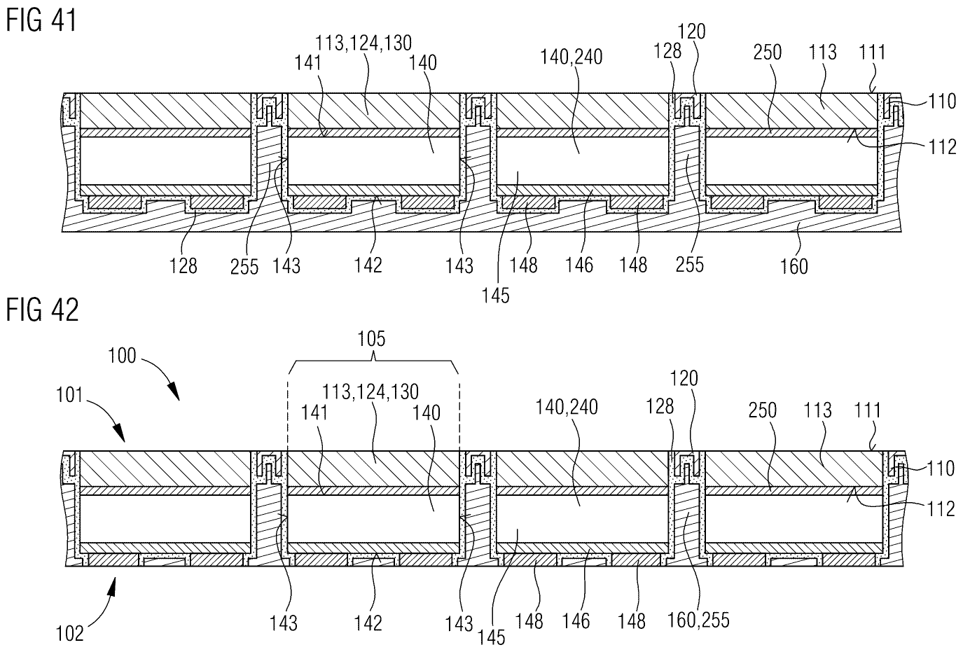

Subsequent to this, or after curing of the stabilization layer 160, as shown in FIG. 42, a part of the stabilization layer 160 as well as a part of the reflective coating 128 present in the region of the contacts 148 of the semiconductor chips 149 are removed in order to expose backside faces of the contacts 148 of the radiation-emitting semiconductor chips 140. For this purpose, grinding, or grinding back, may be carried out. It is possible to use the contacts 148 of the semiconductor chips 140 themselves as contacts for the contacting and electrical supply of the lighting device 100 produced according to the present method sequence. The lighting device 100 may therefore be completed by the grinding back. It is also possible that there is a panel consisting of a plurality of contiguous lighting devices 100 after the grinding back, which may subsequently be separated into a plurality of lighting devices 100 by carrying out singulation. During this process, the conversion element 110 and the stabilization layer 160 are cut between conversion sections 113 and semiconductor chips 140 (not represented).

The method sequence described above, in which a wafer 242 is used, makes it possible to produce the lighting device 100 with constant distances between the light-emitting pixels 105. In this case, use may be made of the fact that the respective position and the distances between the semiconductor chips 140 may be established with high accuracy by the cutting of the wafer 242 connected to the conversion element 110 in order to form the radiation-emitting semiconductor chips 140. Placement variations, such as may occur when mounting individual chips, may be avoided in this case. Consequently, it is also possible to generate the conversion element 110 with conversion sections 113 which have relatively small and constant distances from one another, and in accordance therewith the semiconductor chips 140 may be provided with relatively small and constant distances from one another. In this way, the lighting device 100 may be implemented in such a way that a variation of distances between the pixels 105 is minimal and distances between the pixels 105 are also minimal.

In the lighting device 100 shown in FIG. 42, the lateral side walls 143 of the radiation-emitting semiconductor chips 140 are covered with the reflective coating 128 so that the primary light radiation 201 generated by the semiconductor chips 140 (cf. FIG. 5) can be reflected at these locations. In this configuration, in contrast to the variants described above, it is conceivable to form the stabilization layer 160 as a nonreflective layer and in this respect, in contrast to FIG. 4, merely from a plastic material 161 and without reflective particles 162. During lighting operation of the lighting device 100 depicted in FIG. 42, the primary radiation 201 generated by the semiconductor chips 140 can shine through the conversion sections 113 of the conversion element 110 only via the front sides 141 of the semiconductor chips 140.

The method sequence described above with the use of a wafer 242 may be modified in various ways. For example, it is conceivable to omit the further mechanical coating of the radiation-emitting semiconductor chips 140 and of the conversion element 110 which was explained with the aid of FIG. 41. The stabilization layer 160 may thereby be generated adjoining the semiconductor chips 140. In order to effect radiation reflection at the lateral side walls 143 of the semiconductor chips 140, the stabilization layer 160 may be formed according to the configuration shown in FIG. 4 as a reflective layer. A further variant consists in not using the contacts 148 of the semiconductor chips 140 for the contacting of the lighting device 100, but instead forming a backside contact structure 170 electrically connected to the contacts 148 of the semiconductor chips 140. This may take place after the grinding back in order to expose the contacts 148 (cf. FIG. 42). The contact structure 170 may in this case be formed as described above with reference to FIG. 18. It is also conceivable to omit the grinding back and instead to form a backside contact structure 170 in a manner corresponding to FIGS. 34 and 35, inter alia by opening the stabilization layer 160 in the region of the contacts 148 of the semiconductor chips 140 (not represented in each case).

Further possible modifications may consist in manufacturing the conversion element 110 in such a way that the recesses 124 of the carrier 120 are partially filled with the conversion material 130 and are free from the conversion material 130 in a frontside partial region, or emission-side partial region, and/or in such a way that the conversion material 130 is present in a sedimented form in the recesses 124 of the carrier 120 and phosphor particles 132 of the conversion material 130 are thereby concentrated in the direction of the semiconductor chips 140. This may be implemented by the introducing of the conversion material 130 into the cavities 123 of the carrier 120 being performed in a manner corresponding to FIG. 23, or sedimentation being performed in a manner corresponding to FIGS. 27 and 28 after the introducing of the conversion material 130 into the cavities 123. It is also possible to produce the conversion element 110 with recesses 124 which widen in a direction away from the semiconductor chips 140, by the carrier 120 being provided in a manner corresponding to FIG. 30 with cavities 123 with a cross-sectional shape which broadens in a direction away from the bottom face (not represented in each case).

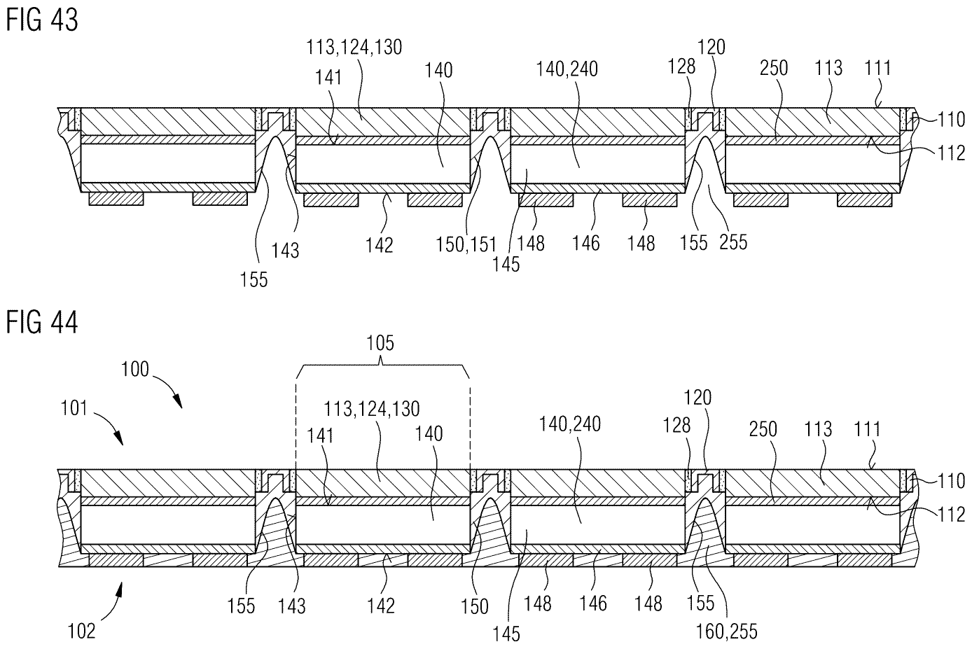

FIGS. 43 and 44 show the production of the lighting device 100 according to a further configuration, which has taken place by using a wafer 242, in a detail with the aid of side sectional representations. In this case, the procedure corresponding to FIGS. 36 to 40 is initially adopted in order to provide the conversion element 110 carrying the emitter group 240 of radiation-emitting semiconductor chips 140. Subsequently, as shown in FIG. 43, a transparent material 151, with which the lateral side walls 143 of the semiconductor chips 140, to a small extent the connecting material 250 and the back side 112 of the conversion element 110 between the semiconductor chips 140 are wetted, is introduced into the partitioning trenches 255 between the semiconductor chips 140. This process may take place by dosing, or dispensing, of the transparent material 151. The wetting of the side walls 143 of the semiconductor chips 140 and of the conversion element 110 takes place in a manner such that the transparent material 151 forms a transparent layer 150, which laterally adjoins the semiconductor chips 140 and in the region of the side walls 143 has a layer surface 155 running curved and/or obliquely with respect to the side walls 143 of the semiconductor chips 140. The transparent layer 150 located inside the partitioning trenches 255 is present in the form of a continuous layer laterally surrounding all the semiconductor chips 140. Inside the partitioning trenches 255, as shown in FIG. 43, the transparent layer 150 may have a cross-sectionally parabolic surface profile. The transparent material 151 employed may be a plastic material, or adhesive material, for example a silicone adhesive.

Subsequently, or after curing of the transparent layer 150, further processes are carried out in order to provide the lighting device 100 shown in FIG. 44. This comprises forming of a reflective stabilization layer 160, which is present laterally with respect to and between the semiconductor chips 140 and adjoins the transparent layer 150. The stabilization layer 160 is also present at the back side of the semiconductor chips 140 and ends flush with backside faces of the contacts 148 of the semiconductor chips 140. The forming of the stabilization layer 160 in order to frame the semiconductor chips 140 may comprise carrying out a molding process or casting process, and optionally grinding back if the stabilization layer 160 initially protrudes beyond the semiconductor chips 140 at the back side. After the forming of the stabilization layer 160, singulation may furthermore take place by cutting the conversion element 110, the transparent layer 150 and the stabilization layer 160 between the conversion sections 113 and the semiconductor chips 140 (not represented).

In the lighting device 100 shown in FIG. 44, not only can the light radiation 201 output through the front side 141 of the semiconductor chips 140 shine through the conversion sections 113 of the conversion element 110, but in addition the component of the light radiation 201 emitted through the lateral side walls 143 (cf. FIG. 5) can be used efficiently. Because of the layer surface 155 of the transparent layer 150 running obliquely and/or curved with respect to the side walls 143 in the region of the side walls 143, the reflective stabilization layer 160 may also have in the region of the semiconductor chips 140 a layer surface running obliquely and/or curved with respect to the side walls 143, and may also form reflector structures surrounding the semiconductor chips 140. With the aid of the stabilization layer 160, a radiation reflection and therefore deviation of the light radiation 201 output through the side walls 143 of the semiconductor chips 140 and coupled into the transparent layer 150 may thereby be induced in the direction of the conversion element 110, so that this radiation component may be supplied to the conversion sections 113 of the conversion element 110 in part by coupling back in, or shining again through the semiconductor chips 140, or their chip substrates 145 (not represented).

For the method sequence explained with the aid of FIGS. 43 and 44, modifications such as have been explained with reference to the method sequence of FIGS. 36 to 42 may be envisioned. For example, it is possible to form a backside contact structure 170 electrically connected to the contacts 148 of the radiation-emitting semiconductor chips 140. Furthermore, the recesses 124 of the carrier 120 of the conversion element 110 may be partially filled with the conversion material 130, the conversion material 130 may be present in a sedimented form in the recesses 124 and/or the recesses 124 of the carrier 120 may have a shape which widens in a direction away from the semiconductor chips 140 (not represented in each case).

Besides the embodiments described above and depicted in the figures, further embodiments which may comprise further modifications and/or combinations of features are also conceivable.

For example, the materials for the lighting device 100 and its constituent parts may be used instead of the materials mentioned above.

For example, it is possible to form the carrier 120 of the conversion element 110 from a ceramic material, from silicone filled with reflective particles or scattering particles (for example TiO2 particles), from a plastic material, from a plastic material with a highly reflective coating, or from glass with a highly reflective coating.

With regard to the method sequences and lighting devices 100 explained with the aid of FIGS. 20 to 44, a further modification consists in forming the conversion element 110 without a reflective coating 128.

Although the invention has been illustrated and described in detail by preferred embodiments, the invention is not restricted by the examples disclosed and other variations may be derived therefrom by a person skilled in the art without departing from the protective scope of the invention.

1.-20. (canceled)

21. A method for producing a lighting device, the method comprising:
providing a structured conversion element having separate conversion sections for radiation conversion arranged next to one another, wherein the conversion element comprises a carrier with recesses, which contain a conversion material, wherein the recesses of the carrier are through-recesses, and wherein a respective conversion section is formed by a recess of the carrier containing the conversion material;
forming an emitter group of radiation-emitting semiconductor chips arranged on the conversion element at one side of the conversion element, wherein a radiation-emitting semiconductor chip is present in a region of each of the conversion sections; and
forming a stabilization layer at least laterally with respect to and between the radiation-emitting semiconductor chips,
wherein forming the emitter group on the conversion element is carried out subsequent to providing of the conversion element, and wherein forming the stabilization layer is carried out subsequent to forming the emitter group on the conversion element.

22. The method according to claim 21, wherein providing the conversion element comprises:
providing the carrier having cavities;
introducing the conversion material into the cavities; and
removing a material at least of the carrier such that the recesses of the carrier containing the conversion material are formed from the cavities of the carrier.

23. The method according to claim 22, wherein introducing the conversion material into the cavities of the carrier comprises partially filling the cavities of the carrier filled with the conversion material, and/or wherein sedimentation takes place after introducing the conversion material into the cavities of the carrier.

24. The method according to claim 22, wherein the cavities of the carrier comprise a bottom face and have a cross-sectional shape that broadens in a direction away from the bottom face.

25. The method according to claim 21, wherein providing the conversion element comprises forming the carrier with a reflective coating, and wherein the reflective coating is present at least in the region of the recesses of the carrier.

26. The method according to claim 21, wherein the radiation-emitting semiconductor chips comprise contacts at a back side, and wherein forming the emitter group on the conversion element takes place such that a front side of the radiation-emitting semiconductor chips faces toward the conversion element.

27. The method according to claim 21, further comprising forming a contact structure connected to contacts of the radiation-emitting semiconductor chips in a region of a side of the radiation-emitting semiconductor chips facing away from the conversion element.

28. The method according to claim 21, wherein the radiation-emitting semiconductor chips are volume emitters.

29. The method according to claim 21, wherein the stabilization layer is a reflective layer.

30. The method according to claim 21, further comprising:
forming a transparent layer adjoining the radiation-emitting semiconductor at least in a region of lateral side walls of the radiation-emitting semiconductor chips,
wherein the transparent layer comprises in the region of the side walls a layer surface running curved and/or obliquely with respect to the side walls of the radiation-emitting semiconductor chips,
wherein the stabilization layer is formed adjoining the transparent layer, and
wherein the stabilization layer forms reflector structures surrounding the radiation-emitting semiconductor chips because of the layer surface of the transparent layer running curved and/or obliquely.

31. The method according to claim 21, wherein forming the emitter group on the conversion element comprises providing the radiation-emitting semiconductor chips as separate radiation-emitting semiconductor chips and arranging the separate radiation-emitting semiconductor chips on the conversion element.

32. The method according to claim 31,
wherein the conversion element comprises indentations in a region of the conversion sections at a side intended for the emitter group,
wherein the radiation-emitting semiconductor chips are arranged in the region of the indentations of the conversion element by using a transparent adhesive material,
wherein, by the adhesive material or by the adhesive material and additionally applying the adhesive material in a region of lateral side walls of the radiation-emitting semiconductor chips, a transparent layer adjoining the radiation-emitting semiconductor chips in a region of a front side and of the side walls is respectively formed,
wherein the indentations of the conversion element act as a stop edge for the adhesive material so that the transparent layer comprises in the region of the side walls a layer surface running curved and/or obliquely with respect to the side walls of the radiation-emitting semiconductor chips,
wherein the stabilization layer is formed adjoining the transparent layer present in the region of the radiation-emitting semiconductor chips, and
wherein the stabilization layer forms reflector structures surrounding the radiation-emitting semiconductor chips because of the layer surface of the transparent layer running curved and/or obliquely.

33. The method according to claim 21, wherein forming the emitter group on the conversion element comprises:
providing a wafer for the radiation-emitting semiconductor chips,
arranging the wafer on the conversion element; and
then cutting the wafer into the radiation-emitting semiconductor chips.

34. The method according to claim 33, further comprising:
applying a transparent material in a region of lateral side walls of the radiation-emitting semiconductor chips in order to form a transparent layer adjoining the radiation-emitting semiconductor chips, which comprises, in the region of the side walls, a layer surface running curved and/or obliquely with respect to the side walls of the radiation-emitting semiconductor chips,
wherein the stabilization layer is formed adjoining the transparent layer, and
wherein the stabilization layer forms reflector structures surrounding the radiation-emitting semiconductor chips because of the layer surface of the transparent layer running curved and/or obliquely.

35. A lighting device comprising:
a structured conversion element having separate conversion sections for radiation conversion arranged next to one another, wherein the conversion element comprises a carrier with recesses which contain a conversion material, wherein the recesses of the carrier are through-recesses, and wherein a respective conversion section is formed by a recess of the carrier containing the conversion material;
an emitter group of radiation-emitting semiconductor chips arranged on the conversion element at one side of the conversion element, wherein a radiation-emitting semiconductor chip is present in a region of each of the conversion sections; and
a stabilization layer arranged at least laterally with respect to and between the radiation-emitting semiconductor chips,
wherein, at least in a region of lateral side walls of the radiation-emitting semiconductor chips, a transparent layer adjoining the radiation-emitting semiconductor chips is located, which comprises in the region of the side walls a layer surface running curved and/or obliquely with respect to the side walls of the radiation-emitting semiconductor chips, and
wherein the stabilization layer adjoins the transparent layer and forms reflector structures surrounding the radiation-emitting semiconductor chips because of the layer surface of the transparent layer running curved and/or obliquely.

36. The lighting device according to claim 35,
wherein the recesses of the carrier are partially filled with the conversion material and are free from the conversion material in an emission-side partial region, and/or
wherein the conversion material is formed in a sedimented form in the recesses of the carrier, and/or
wherein the recesses of the carrier have a cross-sectional shape, which broadens at least partially in a direction away from the side of the conversion element intended for the emitter group.

37. The lighting device according to claim 35, wherein the carrier comprises a reflective coating at least in a region of the recesses.

38. The lighting device according to claim 35,
wherein the radiation-emitting semiconductor chips comprise contacts at a back side, and
wherein a front side of the radiation-emitting semiconductor chips faces toward the conversion element, and/or
wherein the lighting device comprises a contact structure connected to contacts of the radiation-emitting semiconductor chips in a region of a side of the radiation-emitting semiconductor chips facing away from the conversion element.

39. The lighting device according to claim 35,
wherein the radiation-emitting semiconductor chips are volume emitters, and/or
wherein the stabilization layer is a reflective layer.

40. A method for producing a lighting device, the method comprising:
providing a structured conversion element having separate conversion sections for radiation conversion arranged next to one another, wherein the conversion element comprises a carrier with recesses, which contain a conversion material, wherein the recesses of the carrier are through-recesses, and wherein a respective conversion section is formed by a recess of the carrier containing the conversion material;
forming an emitter group of radiation-emitting semiconductor chips arranged on the conversion element at one side of the conversion element, wherein a radiation-emitting semiconductor chip is present in a region of each of the conversion sections; and
forming a stabilization layer at least laterally with respect to and between the radiation-emitting semiconductor chips,
wherein forming of emitter group on the conversion element comprises providing the radiation-emitting semiconductor chips as separate radiation-emitting semiconductor chips and arranging the separate radiation-emitting semiconductor chips on the conversion element.
